(19) United States
(12) Patent Application Publication
(10) Pub. No.: US 2010/0101619 A1
(43) Pub. Date: Apr. 29, 2010

(54) THERMOELECTRIC DEVICE AND METHOD OF MANUFACTURING THE SAME

(75) Inventors: Takahiro SOGOU, Yokohama-shi (JP); Kazuki Tateyama, Yokohama-shi (JP); Hiroyoshi Hanada, Yokohama-shi (JP); Yasuhito Saito, Yokohama-shi (JP); Masayuki Arakawa, Yokohama-shi (JP); Naruhito Kondo, Kawasaki-shi (JP); Osamu Tsuneoka, Setagaya-ku (JP); Naokazu Iwanade, Itabashi-ku (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Kabushiki Kaisha Toshiba, Minato-ku (JP)

(21) Appl. No.: 12/652,063

(22) Filed: Jan. 5, 2010

Related U.S. Application Data
(62) Division of application No. 11/494,529, filed on Jul. 28, 2006.

(30) Foreign Application Priority Data
Aug. 2, 2005 (JP) 2005-224491
Aug. 12, 2005 (JP) 2005-234133
Aug. 22, 2005 (JP) 2005-239819
Sep. 15, 2005 (JP) 2005-268516
Jul. 21, 2006 (JP) 2006-198936

(51) Int. Cl. H01L 35/00

(52) U.S. Cl. 136/200

(57) ABSTRACT

There is provided a thermoelectric device capable of improving a power generation performance while keeping a hermetic sealing after a heat cycle is applied, and also achieving simplification of a structure and improvement in productivity and reliability of a device by reducing the number of articles, and a method of manufacturing the same.

A thermoelectric device, includes a metal substrate 2, a thermoelectric element 3 mounted on a center portion of a surface of the metal substrate 2, a metal lid 4 for covering an upper surface and side surfaces of the thermoelectric element 3, and a joining metal member 5 provided to a peripheral portion of a surface of the metal substrate 2 to hermetically seal a space between the metal substrate 2 and the lid 4.

### CROSS REFERENCE TO RELATED APPLICATION

This application is a division of and claims the benefit of priority under 35 U.S.C. §120 from U.S. Ser. No. 11/494,529 filed Jul. 28, 2006, and claims the benefit of priority under 35 U.S.C. §119 from Japanese Patent Application Nos. 2005-224491 filed Aug. 2, 2005, 2005-234133 filed Aug. 12, 2005, 2005-239819 filed Aug. 22, 2005, 2005-268516 filed Sep. 15, 2005, and 2006-198936 filed Jul. 21, 2006, the entire contents of each of which are incorporated herein by reference.

### BACKGROUND OF THE INVENTION

1. Field of the Invention

The present invention relates to a thermoelectric device and a method of manufacturing the same and, more particularly, a thermoelectric device for converting heat into electricity or converting electricity into heat and a method of manufacturing the same.

2. Discussion of the Background

The thermoelectric device is the device that utilizes the thermoelectric effect such as the Thomson effect, the Peltier effect, the Seebeck effect, or the like. As the devices that have already been mass-produced, the temperature adjusting unit for converting electricity into heat, and the like can be listed. Also, the research and development of the power generator unit for producing electricity from waste heat, for example, is proceeding.

In order to bring a power generation efficiency of the thermoelectric device closer to a power generation efficiency of the thermoelectric element itself, heat supply to one end portion of the thermoelectric element and heat radiation from the other end portion of the thermoelectric element must be executed smoothly. Therefore, the ceramic substrate that is excellent in the heat conduction is used as the insulating substrate constituting the thermoelectric device. Then, the electrode provided to the end portion of the thermoelectric element is composed of the material having a low electric resistance.

Also, when the thermoelectric device is exposed to a high temperature of 200° C., it is demanded that not only should the member exposed directly to heat not be broken down by heat, but also the thermoelectric element and the electrode connecting electrically the thermoelectric element should be hermetically sealed. This is because such a situation should be prevented that the thermoelectric element and the electrode are exposed to the high temperature and oxidized and then the power generation efficiency is deteriorated. In the thermoelectric device, as described above, normally the ceramic substrate is used as the insulating substrate and the ceramic substrate and the case are hermetically sealed by the brazing.

In the thermoelectric device, in order to increase an output of an electromotive force that can be output to the outside, a plurality of thermoelectric elements are aligned on the substrate to be put between the insulating substrates having the electrodes and also connected electrically in series but connected thermally in parallel. However, in some cases there is a variation in the height of individual thermoelectric elements. In this event, such disadvantages are caused that the heat absorbed from the high temperature side cannot be sufficiently supplied to the thermoelectric element, etc. and in some cases a desired power generation performance cannot be obtained. Therefore, there has been proposed the thermoelectric device in which the elastic conductive member is arranged on the other end surface of the thermoelectric element opposing to one end surface to which the substrate is bonded and also the cap-type electrode for covering the conductive member and the thermoelectric element is provided to prevent its movement (see Patent Literature 1).
[Patent Literature 1] Patent Application Publication (KOKAI) 2005-64457

However, in the invention disclosed in Patent Literature 1, such a case may be considered that improvement in the power generation performance of the thermoelectric device becomes difficult. More particularly, when the cap-type electrodes are provided, the insulating plates each having a predetermined height are arranged between the thermoelectric elements on the substrate respectively to prevent the event that these plural electrodes are brought into contact with each other to cause a short circuit. When these insulating plates are arranged, the number of the thermoelectric elements arranged on the substrate is restricted and a rate of the thermoelectric elements a unit area of the substrate is reduced. Therefore, an output density of the thermoelectric device cannot be enhanced and the power generation performance is lowered.

Also, since the thermoelectric device is exposed to a high temperature during its operation, respective members constituting the thermoelectric device are thermally expanded rather than the normal temperature condition. At that time, an amount of deformation of respective members is different respectively due to a difference in coefficients of linear expansion of respective members and a temperature difference between the heat absorption side and the heat radiation side. In particular, since a difference in coefficients of linear expansion between the ceramic substrate and the case is large, the load applied to the brazed portions is increased to generate the breakage, and an airtightness in the thermoelectric device is deteriorated to lower the power generation performance.

In addition, the thermal resistance from the heat source to the thermoelectric elements is affected by type of the member interposed between the heat source and the thermoelectric elements, thickness of the member, and mechanical contact between these members. In particular, since the influence of the mechanical contact is significant, the mechanical contacts between the heat source and the thermoelectric elements must be reduced by reducing the number of articles and also the power generation performance must be improved by reducing the thermal resistance. For example, when a thickness of the external electrode used to output an electromotive force from the thermoelectric device to the outside is thicker than that of the substrate and then a clearance is produced between the substrate of the thermoelectric device and the coolant, the thermal resistance between them is increased and a reduction in the power generation performance is caused.

Also, when the ceramic substrate is fitted to the lid to come in contact with the inner surface of the lid without clearance to attain electrical insulation to the lid, a clearance is produced between the inner surface of the lid and the ceramic substrate because of the machining precision. Thus, a loss of heat transfer to the thermoelectric element is generated by an air layer existing in this clearance. This loss of heat transfer is also generated between the cap-type electrode and the ceramic substrate. These losses of heat transfer result in a reduction in the power generation performance.

### SUMMARY OF THE INVENTION

The present invention has been made to solve the above problems, and it is an object of the present invention to provide a thermoelectric device capable of improving a power generation performance while keeping a hermetic sealing after a heat cycle is applied, and also achieving simplification of a structure and improvement in productivity and reliability of a device by reducing the number of articles, and a method of manufacturing the same.

According to a first aspect of the present invention, there is provided a thermoelectric device, which includes a closed vessel in which an internal space is constructed by metal members and a first principal surface and a second principal surface are opposed mutually at a distance; an insulating layer formed on the first principal surface; a wiring layer provided on a surface of the insulating layer; a plurality of thermoelectric elements one ends of which are secured to the wiring layer to stand upright and which are connected electrically; a metal thin wire net arranged on other ends of the thermoelectric elements to connect electrically the plurality of thermoelectric elements; and an insulating member provided between the metal thin wire net and the second principal surface.

According to a second aspect of the present invention, there is provided a thermoelectric device, which includes a metal substrate; a thermoelectric element mounted on a center portion of a surface of the substrate; a frame body joined to a peripheral portion of the surface of the substrate to surround the thermoelectric element in an inside; a wiring electrode one end of which is connected electrically to the thermoelectric element and other end of which is led frame body on the surface of the substrate on which the frame body is joined; and a lid arranged to oppose to the surface of the substrate via the frame body such that the lid, the substrate, and the frame body seal the thermoelectric element.

According to a third aspect of the present invention, there is provided a thermoelectric device, which includes a metal substrate; a thermoelectric element mounted on a surface of the substrate; a lid arranged to oppose to the surface of the substrate via the thermoelectric element; and a frame body having a high heat resistance shaped portion one end of which is joined to a peripheral portion of the substrate to surround a periphery of the thermoelectric element and other end of which is joined to a peripheral portion of the lid.

According to a fourth aspect of the present invention, there is provided a method of manufacturing a thermoelectric device, which includes a step of forming a wiring layer on a first principal surface constituting a metal closed vessel via an insulating layer; a step of joining a thermoelectric element to the wiring layer via a joining material; a step of mounting a metal thin wire net on the thermoelectric element; and a step of mounting an insulating member on the metal thin wire net to hold the insulating member between the metal thin wire net and a second principal surface constituting a metal closed vessel, and hermetically sealing an internal space that is formed in the metal closed vessel by closing the metal closed vessel by means of a welding.

According to a fifth aspect of the present invention, there is provided a method of manufacturing a thermoelectric device, which includes a step of mounting a thermoelectric element on a substrate; a step of fitting a frame body to a peripheral portion of a surface of the substrate; a step of fixing a metal thin wire net on a spray deposit that is formed on an inner surface of a lid by spraying an insulating material; and a step of arranging the lid to oppose the inner surface of the lid to the surface of the substrate such that the lid pushes the metal thin wire net against other electrode of the thermoelectric element via the spray deposit, and hermetically sealing the thermoelectric element in a space, which is surrounded by the substrate, the lid, and the frame body, by fitting a peripheral portion of the lid to the frame body.

According to a sixth aspect of the present invention, there is provided a method of manufacturing a thermoelectric device, which includes a step of forming a leading wiring on a surface of a metal substrate from a center portion to a peripheral portion; a step of joining a frame body to a peripheral portion of a surface of the substrate to cross the leading wiring; a step of connecting electrically an thermoelectric element to an electrode that is constructed in an area of one end portion of the leading wiring; and a step of fitting a lid to a surface of the substrate via the frame body, and sealing the thermoelectric element in a space that is surrounded by the substrate, the frame body, and the lid.

According to the present invention, the thermoelectric device that is capable of improving a power generation performance while keeping a hermetic sealing after a heat cycle is applied, and also achieving simplification of a structure and improvement in productivity and reliability of a device by reducing the number of articles, and the method of manufacturing the same can be provided.

### BRIEF DESCRIPTION OF THE DRAWINGS

FIG. 1 is a sectional view of a thermoelectric device according to a first embodiment of the present invention;

FIG. 2 is an explanatory view explaining a method of manufacturing the thermoelectric device according to the first embodiment of the present invention;

FIG. 3 is an explanatory view explaining the method of manufacturing the thermoelectric device according to the first embodiment of the present invention;

FIG. 4 is an explanatory view explaining the method of manufacturing the thermoelectric device according to the first embodiment of the present invention;

FIG. 5 is an explanatory view explaining the method of manufacturing the thermoelectric device according to the first embodiment of the present invention;

FIG. 6 is an explanatory view explaining the method of manufacturing the thermoelectric device according to the first embodiment of the present invention;

FIG. 7 is an explanatory view explaining the method of manufacturing the thermoelectric device according to the first embodiment of the present invention;

FIG. 8 is a sectional view of a thermoelectric device according to a first variation of the first embodiment of the present invention;

FIG. 9 is a sectional view of a thermoelectric device according to a second variation of the first embodiment of the present invention;

FIGS. 10A to D are sectional views of major steps of the thermoelectric device shown in FIG. 9;

FIG. 11 is a sectional view of a thermoelectric device according to a third variation of the first embodiment of the present invention;

FIG. 12 is a sectional view of a thermoelectric device according to a fourth variation of the first embodiment of the present invention;

FIG. 13A is a sectional view of a thermoelectric device according to a fifth variation of the first embodiment of the present invention, and FIG. 13B is a plan view of a heat exchange jacket when viewed from a B-B line in an arrow direction in FIG. 13A;

FIG. 14 is a sectional view of another variation of the thermoelectric device according to the fifth variation of the first embodiment of the present invention;

FIG. 15 is a sectional view of a thermoelectric device according to a second embodiment of the present invention;

FIG. 16 is an explanatory view explaining a method of manufacturing the thermoelectric device according to the second embodiment of the present invention;

FIG. 17 is an explanatory view explaining the method of manufacturing the thermoelectric device according to the second embodiment of the present invention;

FIG. 18 is an explanatory view explaining the method of manufacturing the thermoelectric device according to the second embodiment of the present invention;

FIG. 19 is an explanatory view explaining the method of manufacturing the thermoelectric device according to the second embodiment of the present invention;

FIG. 20 is an explanatory view explaining the method of manufacturing the thermoelectric device according to the second embodiment of the present invention;

FIG. 21 is an explanatory view explaining the method of manufacturing the thermoelectric device according to the second embodiment of the present invention;

FIG. 22 is an explanatory view explaining the method of manufacturing the thermoelectric device according to the second embodiment of the present invention;

FIG. 23 is an explanatory view explaining the method of manufacturing the thermoelectric device according to the second embodiment of the present invention;

FIG. 24 is a sectional view of a thermoelectric device according to a first variation of the second embodiment of the present invention;

FIG. 25 is a sectional view of a thermoelectric device according to a second variation of the second embodiment of the present invention;

FIG. 26 is a sectional view of a thermoelectric device according to a third embodiment of the present invention;

FIG. 27A,B,C are an explanatory view showing a method of manufacturing a metal thin wire net with foil according to a fourth embodiment of the present invention;

FIG. 28A,B are an explanatory view showing another method of manufacturing the metal thin wire net with foil according to the fourth embodiment of the present invention;

FIG. 29 is a sectional view of a thermoelectric device according to a fifth embodiment of the present invention;

FIG. 30 is an explanatory view explaining a method of manufacturing the thermoelectric device according to the fifth embodiment of the present invention;

FIG. 31 is a plan view of major steps of the thermoelectric device shown in FIG. 30;

FIG. 32 is an explanatory view explaining the method of manufacturing the thermoelectric device according to the fifth embodiment of the present invention;

FIG. 33 is a plan view of major steps of the thermoelectric device shown in FIG. 32;

FIG. 34 is an explanatory view explaining the method of manufacturing the thermoelectric device according to the fifth embodiment of the present invention;

FIG. 35 is a plan view of major steps of the thermoelectric device shown in FIG. 34;

FIG. 36 is an explanatory view explaining the method of manufacturing the thermoelectric device according to the fifth embodiment of the present invention;

FIG. 37 is an explanatory view explaining the method of manufacturing the thermoelectric device according to the fifth embodiment of the present invention;

FIG. 38 is an explanatory view explaining the method of manufacturing the thermoelectric device according to the fifth embodiment of the present invention;

FIG. 39 is an explanatory view explaining the method of manufacturing the thermoelectric device according to the fifth embodiment of the present invention;

FIG. 40 is a side view of the thermoelectric device when the thermoelectric device shown in FIG. 29 is viewed from the direction D;

FIG. 41 is a sectional view of a thermoelectric device according to a variation of the fifth embodiment of the present invention;

FIG. 42 is a sectional view of a thermoelectric device according to a sixth embodiment of the present invention;

FIGS. 43A,B are explanatory views showing a frame body according to the sixth embodiment of the present invention in an enlarged manner;

FIG. 44 is an explanatory view showing a jointed portion between a lid and the frame body in the sixth embodiment of the present invention in an enlarged manner;

FIG. 45 is a sectional view of a thermoelectric device according to a first variation of the sixth embodiment of the present invention;

FIG. 46 is an explanatory view explaining the frame body according to the first variation of the sixth embodiment of the present invention;

FIG. 47 is an explanatory view explaining a frame body according to a second variation of the sixth embodiment of the present invention;

FIG. 48 is an explanatory view of another variation of the second variation of the sixth embodiment of the present invention; and

FIG. 49 is an explanatory view of still another variation of the second variation of the sixth embodiment of the present invention.

### DETAILED DESCRIPTION OF THE INVENTION

Various embodiments of the present invention will be explained in detail with reference to the drawings hereinafter.

### First Embodiment

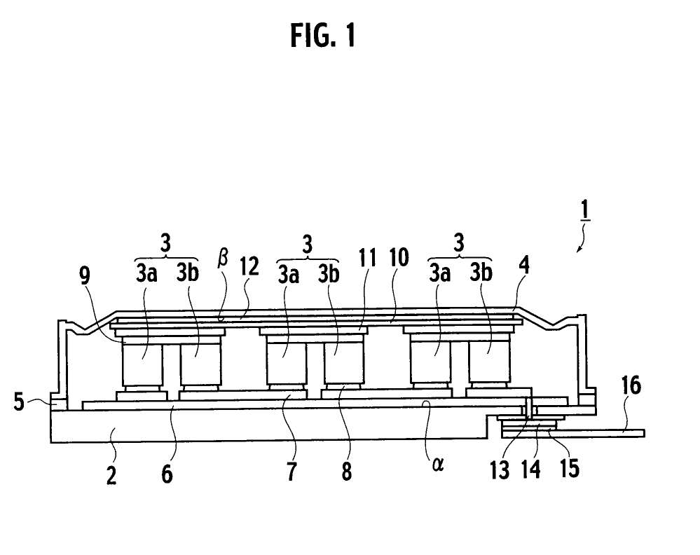

As shown in FIG. 1, a thermoelectric device (closed vessel) 1 according to a first embodiment of the present invention is constructed by a metal substrate 2 made of metal, thermoelectric elements 3 put on a center portion on a surface (referred appropriately to as a “first principal surface α” hereinafter) of the metal substrate 2, a lid 4 for covering upper surfaces and side surfaces of the thermoelectric elements 3, and a joining metal member 5 made of metal to hermetically seal the metal substrate 2 and the lid 4 in a peripheral portion of the first principal surface α. More particularly, all members constituting the vessel (thermoelectric device) 1, i.e., the metal substrate 2, the metal lid 4, and the joining metal member 5, are made of metal.

An insulating layer 6 is provided in the center portion on the first principal surface α, and first conductive wiring layers 7 are formed on the insulating layer 6. As the insulating layer 6, preferably a resin or a resin containing ceramic powders, for example, should be employed. In the first embodiment, concretely copper can be employed as the metal substrate 2 and the first wiring layer 7 and an epoxy resin containing the ceramic powders can be employed as the insulating layer 6. The thermoelectric elements 3 are joined to the first wiring layers 7 via a joining material 8 such as a solder, or the like, for example.

A metal thin wire net 9 as a mesh-like conductive member is arranged on end portions of the thermoelectric elements 3, which are not bonded to the first wiring layers 7, to stretch over a pair of thermoelectric elements 3. Concretely a strap formed by meshing a Cu thin wire of 0.6 mm diameter and cut into a predetermined length can be used as the metal thin wire net 9.

Since the metal thin wire net 9 has an elasticity in the thickness direction, such metal thin wire net 9 can absorb a variation in height of the mounted thermoelectric elements 3. Therefore, the electrical connection between the thermoelectric elements 3 and a second wiring layer 11 can be made sure via the metal thin wire net 9 and also the step of selecting/inspecting the thermoelectric element 3 every length, or the like can be neglected.

An insulating member 10 is arranged on the metal thin wire nets 9. The second wiring layers 11 are formed on a surface (lower surface in FIG. 1) of the insulating member 10, and a metal film 12 is provided on an overall back surface (upper surface in FIG. 1) of the insulating member 10. The metal film 12 contacts a surface (referred to as a “second principal surface β” hereinafter) of the lid 4 opposing to the first principal surface α. A mechanical strength of the insulating member 10 can be increased by putting the insulating member 10 between the second wiring layers 11 and the metal film 12. Also, since the metal film 12 contacts the second principal surface β, an endothermic efficiency can be enhanced.

The lid 4 is formed of metal such as Kovar, stainless (preferably SUS304), or the like, for example, and is metallic jointed to the metal substrate 2 via the joining metal member 5. A metal foil such as a nickel (Ni) foil, or the like can be used as the joining metal member 5. Unlike the ceramic substrate up to now, both the metal substrate 2 and the lid 4 are made of metal. Therefore, a difference in the coefficient of linear expansion between the metal substrate 2 and the lid 4 can be reduced, and a stress generated in the jointed portion between both members following upon the heat cycle can be reduced, and also airtightness can be maintained.

The wiring layers used in the first embodiment are obtained by shaping the metal substrate put on the market into those of the thermoelectric device. As the metal substrate sold widely in common, copper (Cu), aluminum (Al), or the like is used as the metal substrate 2. Also, the first wiring layers 7 obtained by patterning the copper foil are pasted on the first principal surface α of the metal substrate 2 by using the insulating epoxy adhesives containing the fillers. When such commercial metal substrate is utilized, the metallic joining obtained by forming an alloy by means of the welding via the nickel parts is effective in joining the substrate to the alloy such as Kovar, stainless, or the like. For this purpose, the frame-like nickel member having the same outer shape as an outer periphery of the metal substrate is employed as the joining metal member 5 such that the joining metal member 5 can be provided along the outer edge of the metal substrate from which the metal substrate 2 is exposed. When the same material as the lid 4 can be used as the material of the metal substrate 2, the joining metal member 5 is not needed.

The lid 4 is arranged to contact the metal film 12 at its second principal surface β and cover the upper surfaces and the side surfaces of a plurality of thermoelectric elements 3, and joined to the metal substrate 2 via the joining metal member 5 in the peripheral portion of the metal substrate 2. Because the lid 4 and the metal substrate 2 are joined together, the insulating member 10 (the second wiring layers 11) and the metal thin wire nets 9 put on the thermoelectric elements 3 are held and sandwiched by the lid 4 and the metal substrate 2 to apply a pressure in the longitudinal direction of the thermoelectric element 3, i.e., the direction along which a current flows in response to generation of the electromotive force.

A portion of the lid 4 contacting the joining metal member 5 is shaped into the flange shape. The laser welding is applied to the side surface portions, at which the end portion of the flange of the lid 4, the joining metal member 5, and the metal substrate 2 are stacked, over the whole periphery to join them via the alloy that includes nickel in its composition.

In this manner, the thermoelectric device 1 has an internal space surrounded by the metal substrate 2 and the lid 4, and this internal space serves as the closed vessel that is closed from the outside. The inside of the closed vessel is set to a low pressure atmosphere such that the closed vessel is hard to deform and destroy even when exposed to a high temperature. Respective thermoelectric elements 3 are hermetically sealed in the closed vessel that is maintained in the low pressure atmosphere.

As the thermoelectric element 3, there are two types consisting of a p-type thermoelectric element 3a and an n-type thermoelectric element 3b. A plurality of p-type thermoelectric elements 3a and a plurality of n-type thermoelectric elements 3b are alternately connected electrically in series and aligned thermally in parallel from the heat absorption side to the heat radiation side.

In the thermoelectric element 3, the currents generated in the p-type thermoelectric element 3a and the n-type thermoelectric element 3b when a heat is applied are directed in the opposite direction to the direction of the thermal gradient. When the p-type thermoelectric elements 3a and the n-type thermoelectric elements 3b are connected electrically in series by the first wiring layers 7 and the second wiring layers 11, a voltage of the electromotive force is increased.

As the electrical series-connection, for example, the p-type thermoelectric elements 3a and the n-type thermoelectric elements 3b are connected alternately in the row direction and the column direction on the metal substrate 2 respectively, and one first wiring layer 7 is brought electrically into contact with one ends of a pair of p-type thermoelectric element 3a and n-type thermoelectric element 3b respectively in each row. Then, one second wiring layer 11 is brought electrically into contact with the other ends of a pair of adjacent p-type thermoelectric element 3a and n-type thermoelectric element 3b, which are not connected to the common first wiring layer 7, respectively. That is, the p-type thermoelectric element 3a and the n-type thermoelectric element 3b located at the end portion of each row are constructed in such a way that the thermoelectric elements adjacent in the column direction are brought electrically into contact with each other by the first wiring layer 7 or the second wiring layer 11. With such configuration, the current converted from the heat is passed through the p-type thermoelectric element 3a and the n-type thermoelectric element 3b alternately and is output from the external electrode.

A through hole wiring 13 provided to pass through the metal substrate 2 and the insulating layer 6 is connected to a metal layer 14 at a portion of the metal substrate 2 exposed to the outside. Then, this metal layer 14 is connected to an external electrode 16 via a solder 15, and thus the electromotive force generated in the thermoelectric element 3 is taken out to the outside.

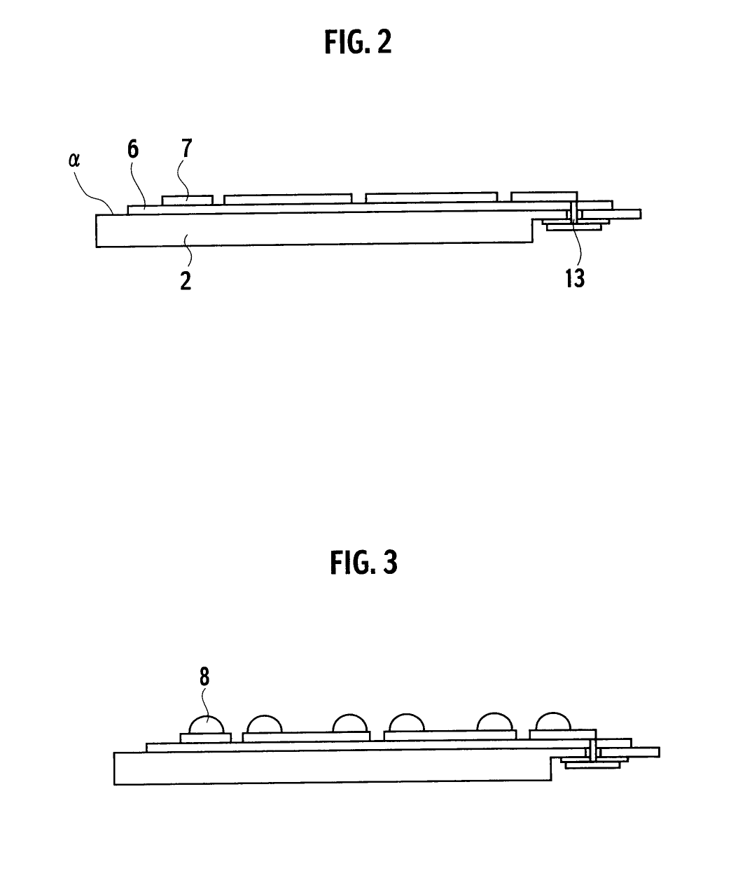

Next, an example of a method of manufacturing (method of assembling) the thermoelectric device 1 will be explained with reference to FIG. 2 to FIG. 7 hereunder.

As shown in FIG. 2, the insulating layer 6 on which the first wiring layers 7 are formed is joined to the metal substrate 2 (the first principal surface α), and also the through hole wiring 13 is formed. The insulating layer 6 is not joined to the overall surface of the first principal surface α, but the insulating layer 6 is joined to the center portion of the metal substrate 2 such that the area to which the insulating layer 6 is not joined is present in the peripheral portion along the periphery of the metal substrate 2 to ensure a joined area where the lid 4 and the metal substrate 2 are joined together.

As shown in FIG. 3, the joining material 8 is coated in predetermined portions of the first wiring layers 7. For example, preferably the solder is used as the joining material 8. But the material is not particularly limited if the similar advantages to those in the first embodiment can be achieved.

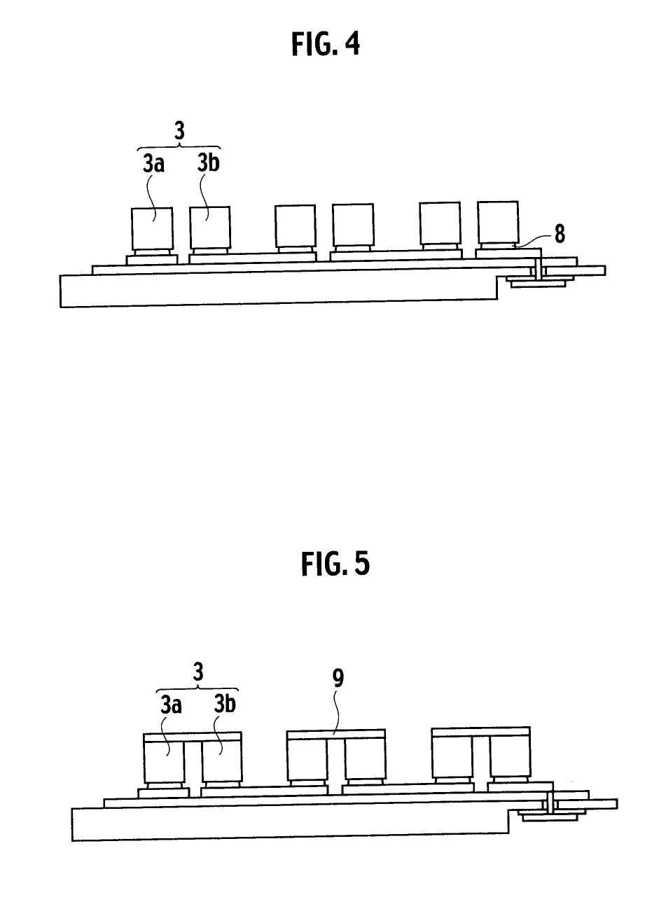

Then, as shown in FIG. 4, a plurality of thermoelectric elements 3a and 3b are put on locations on which the joining material 8 is coated to align with the above arrangement, for example, and the thermoelectric elements 3a and 3b are joined to the first wiring layers 7 respectively. For example, when the solder is employed as the joining material 8, the first wiring layers 7 and the thermoelectric elements 3a and 3b are collectively joined together in the reflow furnace respectively.

As shown in FIG. 5, the metal thin wire net 9 is put on the thermoelectric elements 3a and 3b to extend over them (to connect electrically them). In this step, the metal thin wire net 9 is not joined to the thermoelectric elements 3 but placed simply thereon.

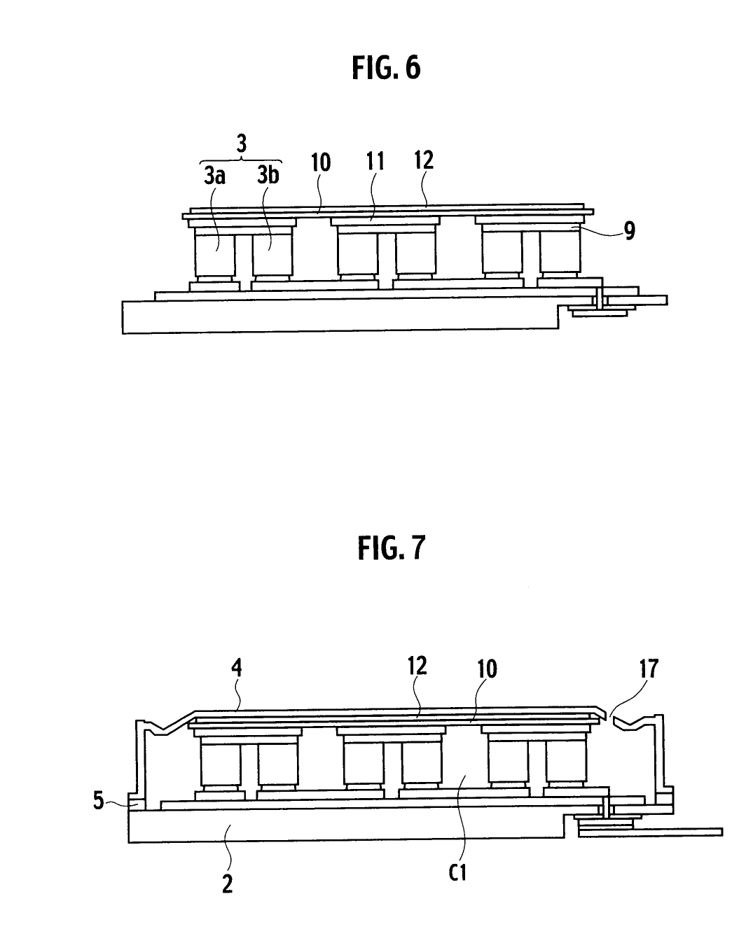

Then, the insulating member 10 on the surface and the back surface of which the second wiring layers 11 and the metal film 12 are provided in advance respectively is loaded on the metal thin wire nets 9 that have been put on the thermoelectric elements 3. As apparent from FIG. 6, the second wiring layers 11 are provided only within a range where they contact the metal thin wire nets 9. In this step, the insulating member 10 is not joined to the metal thin wire nets 9 but placed simply on the metal thin wire nets 9.

Then, as shown in FIG. 7, the lid 4 is arranged to contact the metal film 12 on the insulating member 10 and cover the upper surfaces and the side surfaces of the thermoelectric elements 3, and also the side portion of the lid 4 is placed on the peripheral surface portion, to which the above insulating layer 6 is not joined, of the metal substrate 2. Then, the lid 4 and the metal substrate 2 are joined together via the joining metal member 5. In the first embodiment, SUS304 is used as the material of the lid 4 and Ni is used as the joining metal member 5. But the materials of the lid 4 and the joining metal member 5 are not limited to these materials if the hermetic sealing can be maintained.

An internal space C1 in which the thermoelectric element 3 is placed is produced between the lid 4 and the joining metal member 5 by joining them in this manner. This internal space C1 is set to a low pressure atmosphere by reducing a pressure from an atmospheric pressure via a sealing hole 17, which is provided previously to the lid 4, by 0.07 MPa, for example. Also, the internal space C1 is brought into a nonoxidizing atmosphere by filling nitrogen, argon, or the like, and then the sealing hole 17 is melt by the laser to hermetically seal the internal space. Accordingly, the thermoelectric device 1 having the hermetic sealing structure can be obtained. Then, the external electrodes 16 to output the electricity generated by the thermoelectric device 1 to the outside are fitted to the portions of the through hole wiring 13. The through hole wiring 13 provided to the thermoelectric device 1 is not limited to one, and a plurality of through hole wirings may be provided.

In this manner, since the metal lid 4 is joined to the metal substrate 2 via the joining metal member 5, a difference of the coefficients of thermal expansions between respective members constituting the external casing of the thermoelectric device 1 can be reduced. Therefore, even when the thermoelectric device 1 is exposed to a high temperature, the joined portion between the metal substrate 2 and the lid 4 is not destroyed and the hermetic sealing is never lost. As a result, the power generation performance of the thermoelectric element 3 provided in the internal space C1 of the thermoelectric device 1 can be improved, the thermoelectric device 1 that is excellent in reliability can be realized, and the thermoelectric device 1 can be manufactured simply.

(First Variation)

Next, a first variation of the first embodiment will be explained hereunder. In the first embodiment and subsequent variations of the first embodiment, the same reference symbols are affixed to the same constituent elements as those explained in the first embodiment, and thus their redundant explanations of the same constituent elements will be omitted herein.

A configuration of the first variation is different from the configuration of the first embodiment in that the lid 4 is divided into the main body of the lid 4 and a frame body 4a and the metal substrate 2 is joined to the frame body 4a. That is, the lid 4 is joined to the peripheral portion of the surface of the metal substrate 2 via the joining metal member 5 in the first embodiment, while the frame body 4a is joined to the peripheral portion of the back surface of the metal substrate 2 in the first variation.

The thermoelectric device 1 generates the electricity from the absorbed heat by using the thermoelectric elements 3. In order to improve a thermoelectric transforming efficiency by generating the larger output, a larger number of thermoelectric elements 3 must be arranged per unit area on the first principal surface α. However, when the lid 4 is joined to the metal substrate 2 at the peripheral portion of the first principal surface α, a predetermined joining area is needed to join the lid 4 to the metal substrate 2, so that a surface area of the first principal surface α required to arrange the thermoelectric elements 3 is reduced. Therefore, in the thermoelectric device 1 according to the first variation, a joining area between the lid 4 and the metal substrate 2 can be sufficiently secured while improving a packaging efficiency of the thermoelectric elements 3 on the first principal surface α.

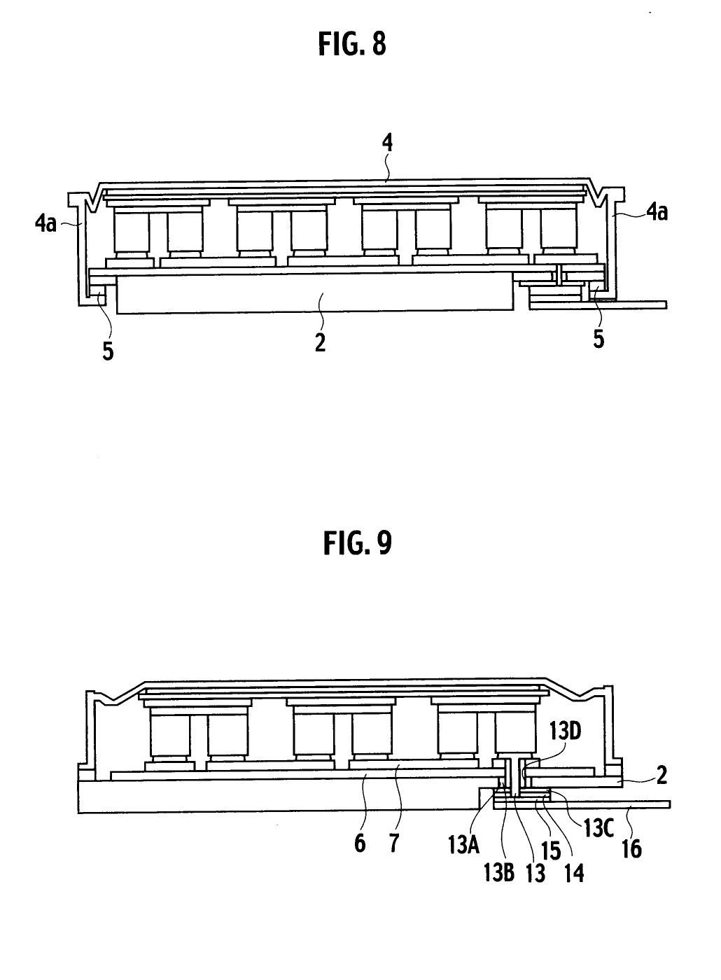

More particularly, as shown in FIG. 8, the frame body 4a of the portion for covering the side surfaces of the thermoelectric elements 3 is constructed to go around to the back surface of the metal substrate 2, and the frame body 4a and the peripheral portion of the back surface of the metal substrate 2 are joined together via the joining metal member 5. Therefore, the joining area to the frame body 4a can be secured sufficiently on the back surface of the metal substrate 2 in comparison with the first principal surface α. A thickness of the metal substrate 2 in this joining area (the peripheral portion of the back surface of the metal substrate 2) is set thinner than that of a center portion of the back surface of the metal substrate 2. Thus, an alignment of the joining metal member 5 can be made easily, and also the frame body 4a (the joining area) is not protruded from the center portion of the back surface of the metal substrate 2.

In this fashion, the frame body 4a is joined to the back surface of the metal substrate 2. Therefore, the first principal surface α can be utilized effectively as the mounting area of the thermoelectric elements 3 not to provide the joining area, and thus a larger number of thermoelectric elements 3 can be arranged on the first principal surface α. As a result, the power generation efficiency of the thermoelectric device 1 can be improved further more while maintaining the hermetic sealing.

(Second Variation)

Next, a second variation of the first embodiment will be explained hereunder.

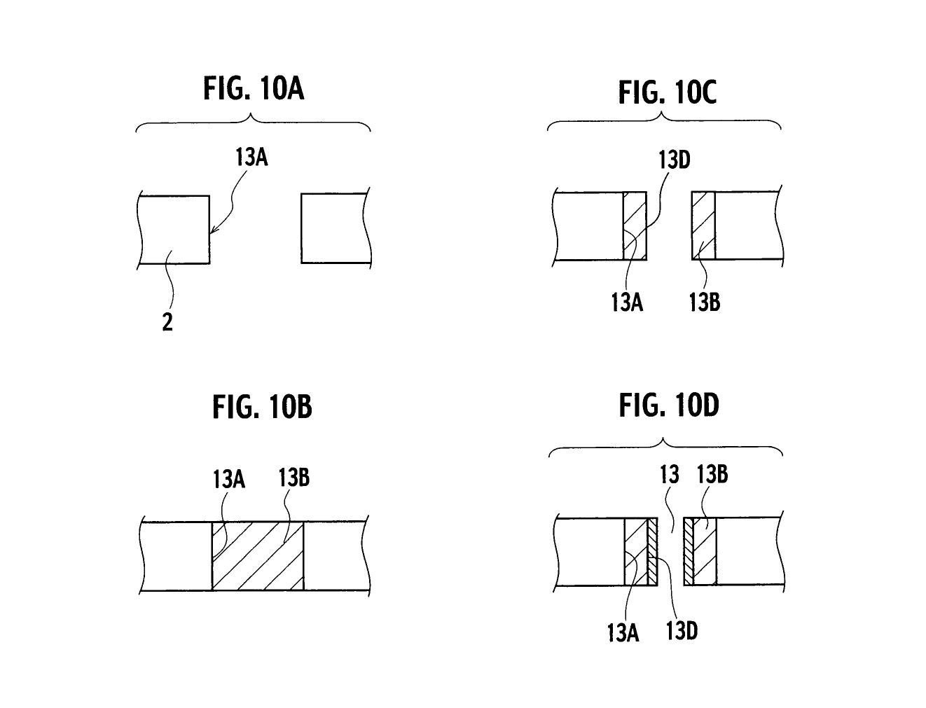

In the second variation, unlike the first embodiment, a configuration of the through hole wiring 13 is different as shown in FIG. 9. More particularly, in the second variation, as shown in FIG. 10A, first a through hole 13A is formed previously in the metal substrate 2 to form the through hole wiring 13. Then, as shown in FIG. 10B, the insulating material 13B is filled in the through hole 13A to stop up the through hole 13A formed in the metal substrate 2 once. Then, the insulating layer 6 having the first wiring layers 7 on the first principal surface α is joined, and also an insulating layer 13C and the metal layer 14 (both are not shown in FIG. 10) are joined to the back surface of the metal substrate 2. Therefore, the metal layer 14, the insulating layer 13C, the metal substrate 2, the insulating layer 6, and the first wiring layers 7 are formed in order when viewed from the bottom (see FIG. 9).

In this state, as shown in FIG. 10C, a through hole 13D passing through respective foregoing layers is formed. The through hole 13D is formed by the machining using the drill, for example. Also, the through hole 13D may be formed by the punching. As shown in FIG. 10D, the through hole wiring 13 is formed along at least the inner wall of the through hole 13D. The through hole wiring 13 can be formed by the plating, for example. Then, the external electrode 16 is joined to the metal layer 14 via the solder 15.

Because such method of manufacturing the through hole wiring 13 is employed, the internal space C1 in the thermoelectric device 1 can be hermetically sealed and the power generation performance of the thermoelectric element 3 can be improved. As a result, not only can the thermoelectric device 1 that is excellent in reliability and the method of manufacturing the same be accomplished, but also the through hole wiring 13 can be manufactured simply not to use the special jig, or the like in manufacturing the through hole wiring 13.

(Third Variation)

Next, a third variation of the first embodiment will be explained hereunder.

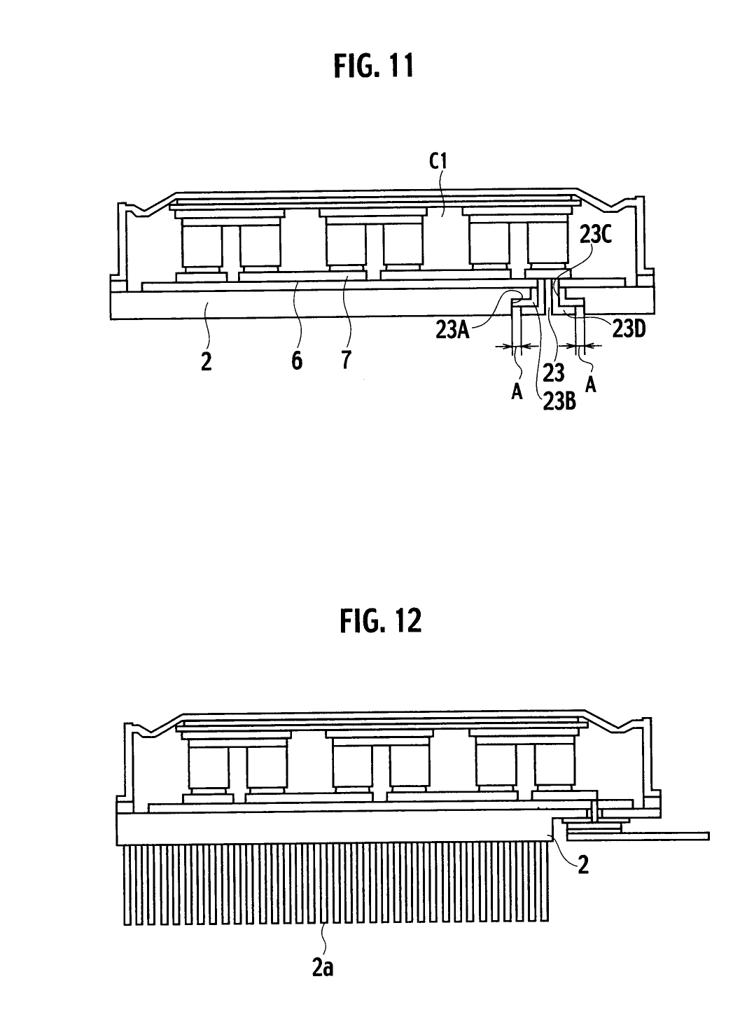

As shown in FIG. 11, unlike the first embodiment, the third variation is different in a configuration of a through hole wiring 23. First, a through hole 23A is formed previously to form the through hole wiring 23 in the metal substrate 2. This through hole 23A is formed such that its diameter on the back surface is opened larger than a diameter on the surface (the first principal surface α) of the metal substrate 2. Then, insulating material 23B is filled in the through hole 23A to bury the through hole 23A formed in the metal substrate 2 once. In this case, the insulating material 23B is filled not to bury completely the through hole 23A but to form a recess when viewed from the back surface of the metal substrate 2.

Then, the insulating layer 6 having the first wiring layers 7 thereon is joined to the surface of the metal substrate 2, and a through hole 23C passing through respective layers except the first wiring layers 7 is formed. The through hole 23C is formed by the machining using the drill, for example. Also, the through hole 23C may be formed by the punching.

Then, the through hole wiring 23 is formed on an inner wall of the through hole 23C, and also a land portion 23D is formed to contact the insulating material 23B and form a coplanar surface with the back surface of the metal substrate 2. The through hole wiring 23 and the land portion 23D can be formed by the plating, for example. Then, although not shown in FIG. 11, the external electrode 16 is joined via the solder 15.

Because such method of manufacturing the through hole wiring 13 is employed, the internal space C1 in the thermoelectric device 1 can be hermetically sealed and the power generation efficiency of the thermoelectric elements 3 can be improved. As a result, the thermoelectric device 1 that is excellent in reliability and the method of manufacturing the same can be implemented, and also a size of the land portion 23D to be formed can be decided freely in design. More particularly, as shown by A in FIG. 11, since a distance between the land portion 23D and the metal substrate 2, i.e., an insulation distance can be decided freely, the insulation between the land portion 23D and the metal substrate 2 is made more certain. Also, since an area of the jointing portion between the external electrode 16 and the land portion 23D can be maximized with regard to a balance to the insulation distance, the joining between the external electrode 16 and the land portion 23D can be strengthened more simply.

In the third variation, the through hole 23A is opened as a stepped hole. However, the hole having any profile such as a tapered hole, for example, may be opened if the hole on the back surface of the metal substrate 2 is opened larger than the hole on the surface, i.e., if the hole is opened to reduce a diameter from the back surface of the metal substrate 2 to the surface.

Also, like the land portion 23D in the third variation, it is desirable from an aspect of installation that the land portion 23D constitutes a coplanar surface. But it is not always required that the land portion 23D should be formed as the coplanar surface. However, preferably the consideration should be taken not to disturb a contact between the metal substrate 2 and the cold heat source.

(Fourth Variation)

Next, a fourth variation of the first embodiment will be explained hereunder.

As shown in FIG. 12, the thermoelectric device 1 according to the fourth variation has such a feature that fins 2a are provided to the back surface of the metal substrate 2. In the fourth variation, a metal that is easily worked by the machining is employed as the metal substrate 2, these fins 2a can be manufactured by applying the cutting, the etching, or the like to the back surface of the metal substrate 2.

In other words, the fins 2a whose heat radiation effect is high are provided to the back surface of the metal substrate 2 acting as the heat radiation side. Therefore, the heat radiation efficiency of the thermoelectric device 1 can be improved, and also the power generation performance of the thermoelectric element 3 can be improved much more. As a result, the power generation performance of the thermoelectric device 1 can be improved further more.

Here, the fins 2a are not manufactured by working the back surface of the metal substrate 2, but the fins 2a manufactured as the separate body from the metal substrate 2 may be fitted onto the back surface of the metal substrate 2.

(Fifth Variation)

Next, a fifth variation of the first embodiment will be explained hereunder.

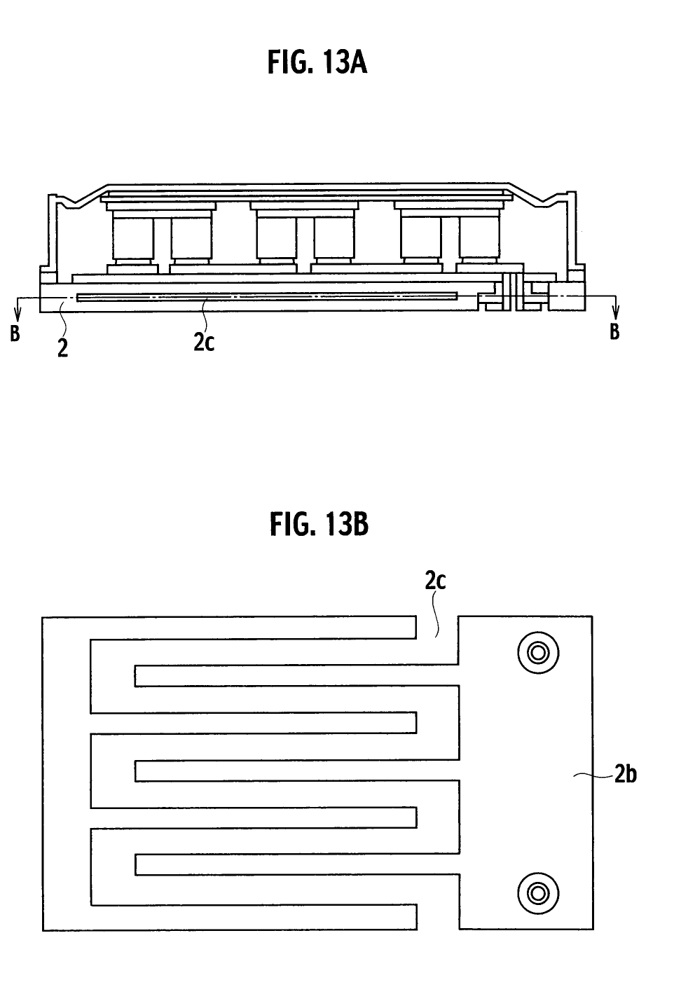

As shown in FIG. 13A and FIG. 13B, a feature of the thermoelectric device 1 according to the fifth variation resides in that the metal substrate 2 has a heat exchange jacket function. FIG. 13B is a view showing a heat exchange jacket 2b being cut along an B-B line in FIG. 13A as a plan view.

More particularly, the heat exchange jacket function is constructed by providing a flow path 2c, which is laid in the inside of the metal substrate 2 of the thermoelectric device 1 to circulate the medium. In order to attain a uniform and high heat exchanging efficiency, the flow path 2c is laid to zigzag through the overall area of the metal substrate 2 except the connection area to the external electrode 16. In case the metal substrate 2 is manufactured by pasting two sheets of substrates together and then the flow path 2c is formed in at least one of pasted substrates by the machining, the etching, or the like, the heat exchange jacket function can be provided simply to the metal substrate 2.

The heat exchange jacket function having a high heat exchange effect is provided to the metal substrate 2. Therefore, the heat exchange efficiency of the thermoelectric device 1 can be improved, and also the power generation performance of the thermoelectric element 3 can be improved. As a result, the power generation performance of the thermoelectric device 1 can be improved much more.

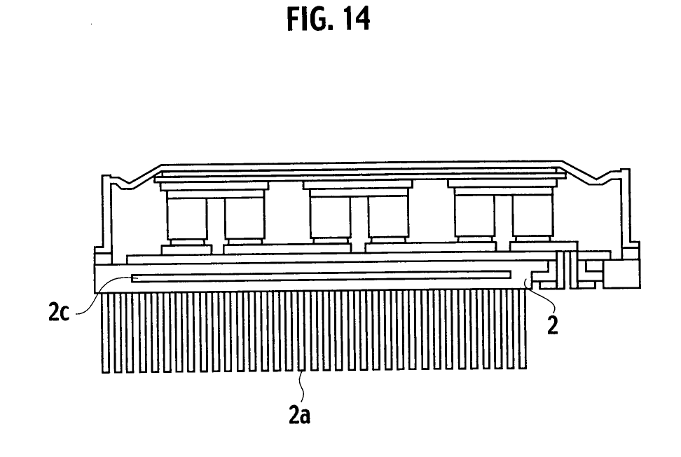

Like the thermoelectric device 1 according to the above fourth variation, in the thermoelectric device 1 according to the fifth variation, the heat exchange jacket 2b manufactured as the separate body from the metal substrate 2 may be fitted onto the back surface of the metal substrate 2. Also, as shown in FIG. 14, the fins 2a described in the fourth variation may be fitted to increase a surface area.

### Second Embodiment

Next, a second embodiment will be explained hereunder. In the second embodiment and respective variations of the second embodiment, the same reference symbols are affixed to the same constituent elements as those explained in the first embodiment, and thus their redundant explanations of the same constituent elements will be omitted herein.

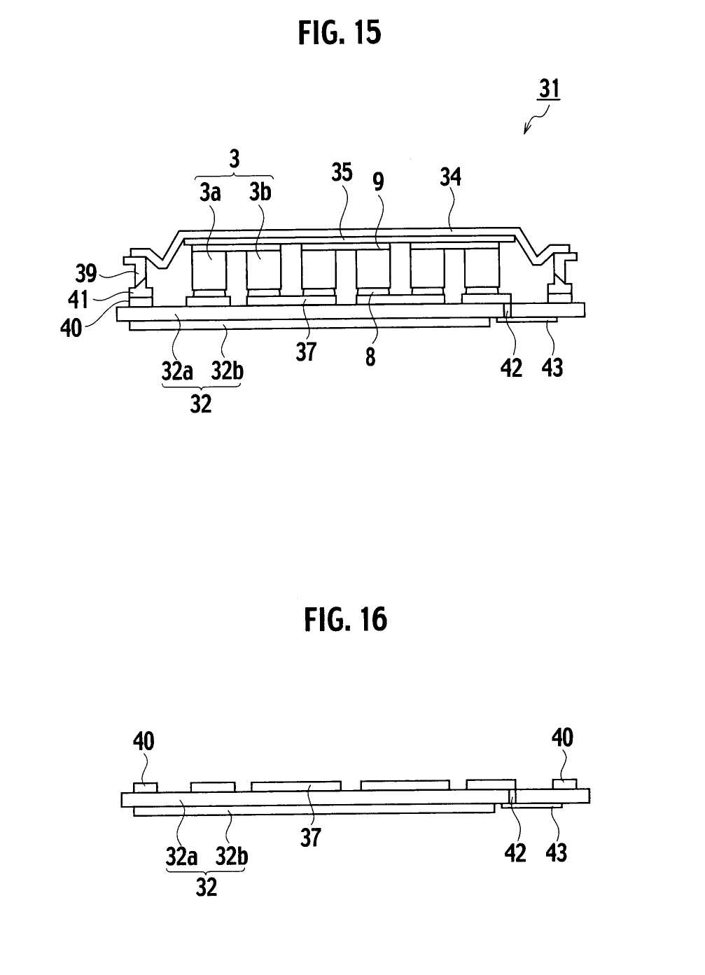

As shown in FIG. 15, a thermoelectric device 31 according to the second embodiment of the present invention includes a substrate 32, the thermoelectric elements 3 on the substrate 32, and a lid 34, and also includes a spray deposit 35 formed to contact tightly an inner surface of the insulating lid 34.

The substrate 32 is constructed by an insulating substrate 32a, a metal film 32b provided on the insulating substrate 32a, and wiring layers 37. Here, the surface of the substrate 32 means the surface on which the thermoelectric elements are loaded, and the back surface of the same means the surface on which the metal film 32b is provided. As the insulating substrate 32a, for example, a resin or a resin containing ceramic powders in addition to the ceramic plate as shown in FIG. 15 in the second embodiment, may be preferably employed. Also, the metal film 32b may be formed on the back surface of the insulating substrate 32a by the welding, the deposition, or the like, for example. As the metal film 32b, for example, copper may be preferably employed. The thermoelectric elements 3 are joined to the wiring layers 37 on the surface of the insulating substrate 32a via the joining material 8 such as the solder, or the like, for example.

As the thermoelectric element 3, there are two types consisting of the p-type thermoelectric element 3a and the n-type thermoelectric element 3b. A plurality of p-type thermoelectric elements 3a and a plurality of n-type thermoelectric elements 3b are alternately connected electrically in series and aligned thermally in parallel from the heat absorption side to the heat radiation side.

The lid 34 is formed of metal such as Kovar, stainless (preferably SUS304), or the like, for example, and the spray deposit 35 is provided to contact tightly the inner surface of the lid 34. Here, the inner surface of the lid 34 means the surface that opposes to the surface of the substrate 32 via the thermoelectric elements 3. A surface of the lid 34 contacting the outside when the thermoelectric device 31 is completed is assumed as an outer surface.

The insulating ceramic material is used as the spray deposit 35. As this ceramic material, for example, white alumina, gray alumina, magnesia spinel, chromia, zircon, or the like, which has electric insulation property and wear resistance and is compatible with Kovar or stainless, for example, constituting the lid 34 may be selected appropriately and then sprayed. Here, an overall surface of the lid 34 may be set as a spray range of the spray deposit 35 on the inner surface of the lid 34. But the spray deposit 35 must be formed such an extent that such spray deposit 35 covers at least an area where the thermoelectric elements 3 are aligned.

The lid 34 is arranged in a position that covers the upper surfaces of plural thermoelectric elements 3, and is joined to a frame body 39. When the lid 34 and the frame body 39 are joined to each other, the metal thin wire net 9 put on the thermoelectric elements 3 is pressed with the lid 34, the frame body 39, and the substrate 32 to apply a pressure in the longitudinal direction of the thermoelectric elements 3, i.e., the direction along which a current flows due to generation of an electromotive force.

A portion of the frame body 39 contacting the lid 34 is shaped into a flange shape. The side surface portion of the lid 34 on which the flange end portion of the frame body 39 is superposed is welded over its full circumstance by the laser welding.

The metal thin wire net 9 serving as the mesh-like conductive member is arranged on the end portions of the thermoelectric elements 3, which are not bonded to the wiring layers 37, to stretch over a pair of thermoelectric elements 3.

The frame body 39 is joined to the insulating substrate 32a via bonding adhesive material 41 on a frame connecting electrode 40 that is provided on the peripheral portion of the surface of the insulating substrate 32a. That is, the frame body 39 surrounds the thermoelectric elements 3 and connects the substrate 32 and the lid 34. As the bonding adhesive material 41, for example, the brazing filler metal is preferably employed.

In this fashion, the thermoelectric device 31 has a space in its inside surrounded by the substrate 32, the lid 34, and the frame body 39. This internal space constitutes a box-shaped structure that is hermetically sealed from the outside. The inside of the box-shaped structure is set to a low pressure atmosphere such that this box-shaped structure is hard to deform and destroy even when exposed to a high temperature. Respective thermoelectric elements 3 are hermetically sealed in the box-shaped structure in which the low pressure atmosphere is maintained.

A through hole wiring 42 provided to pass through the insulating substrate 32a is connected to external electrode 43 on the portion of the insulating substrate 32a exposed outward, via the joining material (not shown). Thus, the electromotive force generated in the thermoelectric elements 3 is taken out to the outside.

Next, an example of a method of manufacturing (method of assembling) the thermoelectric device 31 will be explained with reference to FIG. 16 to FIG. 23 hereunder.

As shown in FIG. 16, first the substrate 32 except the lid 34 in the thermoelectric device 31 is manufactured. The wiring layers 37 are joined to the surface of the substrate 32 consisting of the insulating substrate 32a and the metal film 32b, and also the through hole wiring 42 and the external electrode 43 are formed. The wiring layers 37 are not joined to the overall surface of the substrate 32, but joined to the center portion of the substrate 32 such that the area to which the wiring layers 37 are not joined is present on the peripheral portion along the periphery of the substrate 32 to secure the joining area to the frame body 39 on the surface of the substrate 32. The peripheral portion of the substrate 32 is used as the joining area between the frame body 39 and the substrate 32, and the frame connecting electrode 40 is formed thereon.

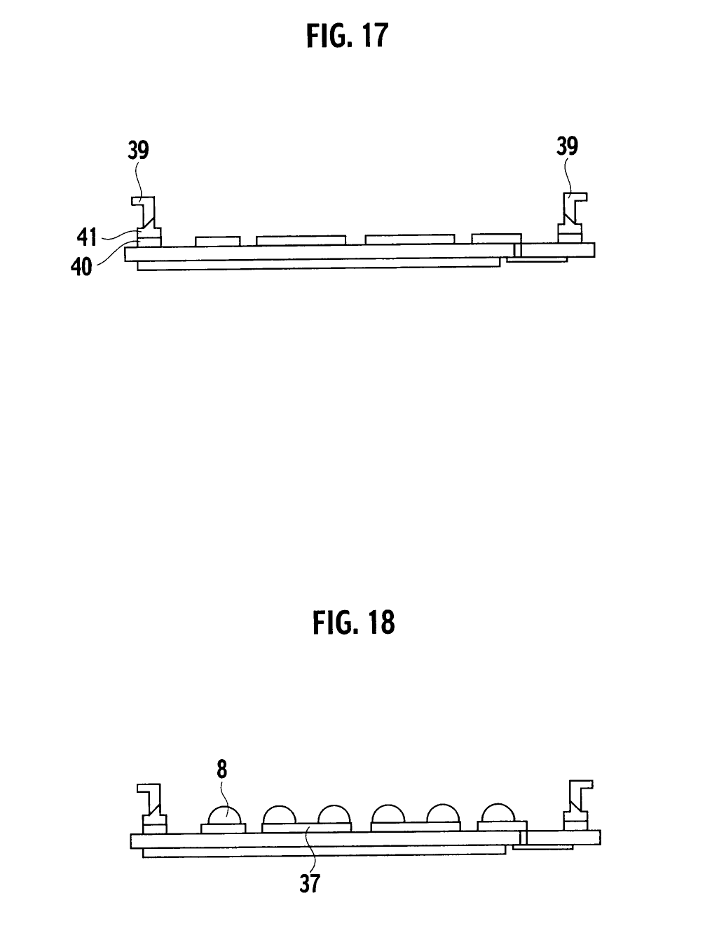

As shown in FIG. 17, the frame body 39 is joined onto the frame connecting electrode 40 formed on the substrate 32 via the bonding adhesive material 41.

As shown in FIG. 18, the joining material 8 is coated on predetermined portions of the wiring layers 37. As the joining material 8, for example, the solder is preferably employed. But the material is not particularly limited if the similar effects to those in the second embodiment can be achieved.

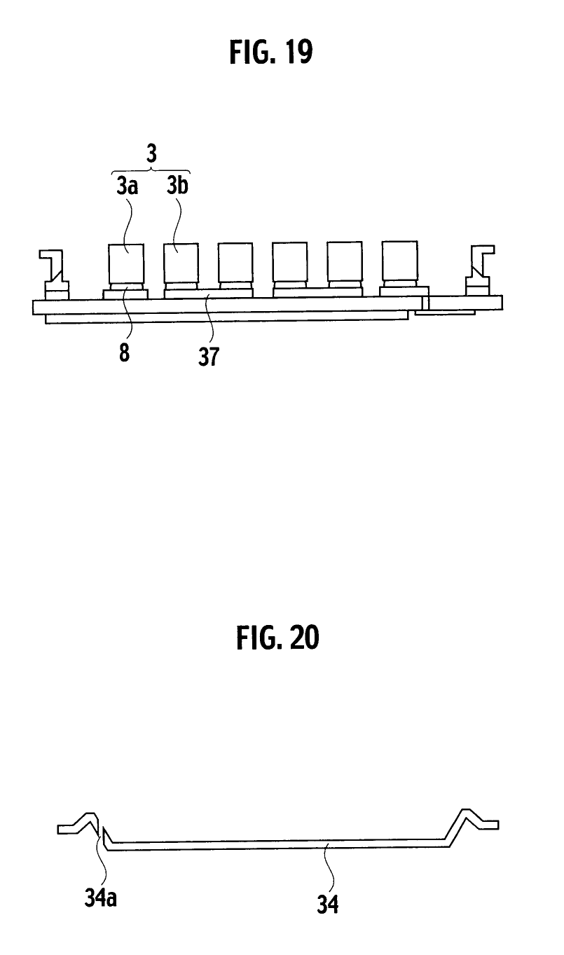

As shown in FIG. 19, a plurality of thermoelectric elements 3a, 3b are put on the locations, on which the joining material 8 is coated, in compliance with the alignment described in the first embodiment, for example, and then the thermoelectric elements 3a, 3b are joined to the wiring layers 37 respectively. When the solder is used as the joining material 8, for example, the thermoelectric elements 3a, 3b are joined collectively to the wiring layers 37 in the reflow furnace respectively.

Then, the lid 34 is manufactured. As shown in FIG. 20, the lid 34 is loaded to direct its outer surface downward (direct its inner surface upward). A sealing hole 34a is formed previously in the lid 34.

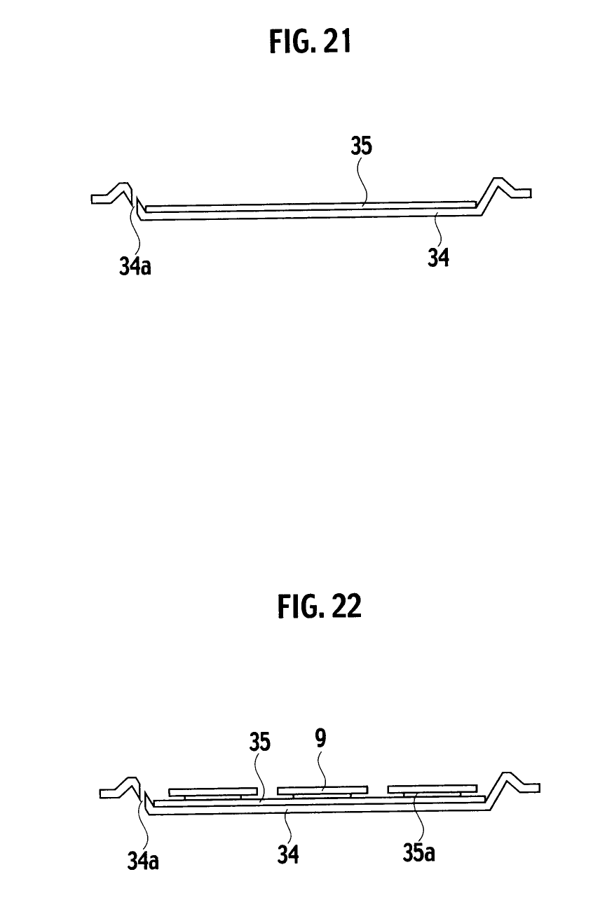

Then, as shown in FIG. 21, the spray deposit 35 is formed on the inner surface of the lid 34. As described above, for example, the white alumina, or the like is preferably employed as the spray deposit 35. But the material is not particularly limited if the similar effects to those in the second embodiment can be achieved.

As shown in FIG. 22, a heat resistant adhesive 35a is coated on the spray deposit 35 and then the metal thin wire nets 9 as the conductive member are jointed thereto. In the second embodiment, inorganic adhesive material is used as the heat resistant adhesive 35a not to generate a gas, or the like even when the thermoelectric device 31 is used at a high temperature. The heat resistant adhesive 35a may be coated in an amount enough to temporarily secure the metal thin wire net 9. Also, portions on which the heat resistant adhesive 35a is coated swell to form unevennesses on the spray deposit 35. In this case, because the metal thin wire net 9 is deformed along the unevennesses, such unevennesses can be absorbed by the metal thin wire net 9 when the metal thin wire net 9 is brought into contact with the thermoelectric elements 3. Here, even when only the metal thin wire nets 9 are put on the predetermined positions of the spray deposit 35 not to use the heat resistant adhesive 35a, the similar advantages to those in the present embodiment can be achieved.

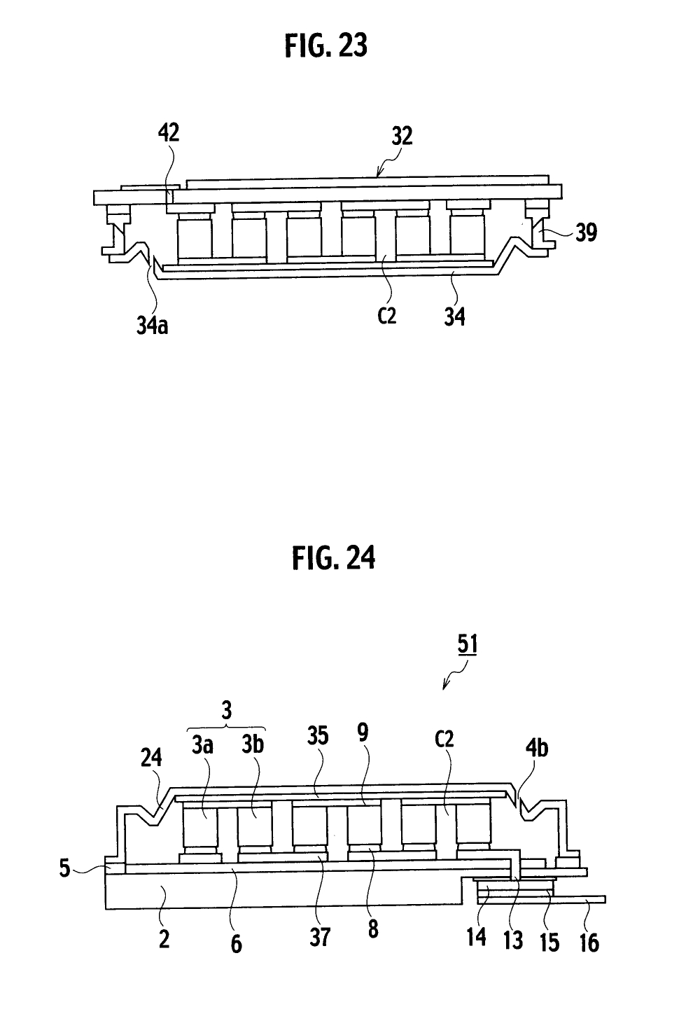

Then, the substrate 32 and the lid 34 manufactured respectively in this manner are joined to each other to oppose the surface of the substrate 32 to the inner surface of the lid 34 via the frame body 39. In FIG. 23, such a case is supposed that the spray deposit 35 and the metal thin wire nets 9 are joined mutually without the heat resistant adhesive 35a in the manufacturing steps of the lid 34. In other words, the metal thin wire nets 9 are put simply on the spray deposit 35 formed on the inner surface of the lid 34, so that the metal thin wire nets 9 fall when the inner surface of the lid 34 is directed downward during the joining to the substrate 32. For this reason, the lid 34 and the frame body 39 are joined to each other in such a manner that the substrate 32 is positioned to direct the thermoelectric elements 3 downward and then the substrate 32 is put on the lid 34.

In contrast, when the metal thin wire nets 9 are fixed to the spray deposit 35 via the heat resistant adhesive 35a, the metal thin wire nets 9 do not fall. Therefore, the particular joining procedures are not required unlike the above case, and either of the substrate 32 and the lid 34 may be joined to the other.

In this manner, because the substrate 32 and the lid 34 are joined to each other to oppose the surface of the substrate 32 to the inner surface of the lid 34 via the frame body 39, an internal space C2 in which the thermoelectric elements are aligned between them is produced. An inside of the internal space C2 is set to the low pressure atmosphere by utilizing the sealing hole 34a that is provided previously in the lid 34. In the second embodiment, a pressure is reduced from the atmospheric pressure by 0.07 MPa, for example, or the atmosphere is also set to the nonoxidizing atmosphere by filling nitrogen, argon, or the like, and then the internal space C2 is hermetically sealed by fusing the sealing hole 34a by means of the laser. Accordingly, the thermoelectric device 31 having a hermetically sealed structure can be obtained. In this case, the number of the through hole wiring 42 provided to the thermoelectric device 31 is not limited to one, and a plurality of through hole wirings 42 may be provided.

According to the thermoelectric device 31 manufactured in this manner, there is no need to provide the cap-type electrode and the insulating plate, and merely the spray deposit 35 and the metal thin wire nets 9 are provided between the inner surface of the lid 34 and the thermoelectric elements 3. Therefore, since a larger number of thermoelectric elements 3 can be provided on the surface of the substrate 32, the output density can be increased and also mechanical contacts between the heat source and the thermoelectric elements are reduced by reducing the number of articles to lower the heat resistance. As a result, the thermoelectric device 31 capable of improving the power generation performance can be realized, and also the thermoelectric device 31 can be manufactured at a low cost and with good productivity.

(First Variation)

Next, a first variation of the second embodiment of the present invention will be explained hereunder.

In the second embodiment, the lid 34 and the frame body 39 are formed of the metal. The first variation is different from the second embodiment in that the substrate 32 is also formed of the metal and also the lid 34 is shaped differently. That is, the spray deposit 35 in the second embodiment is provided to the thermoelectric device 1 of the first embodiment.

As shown in FIG. 24, a thermoelectric device 51 according to the first variation of the second embodiment includes the metal substrate 2, the thermoelectric elements 3 put on the surface of the metal substrate 2, and a lid 24 having an upper wall whose inner surface opposes to the surface of the metal substrate 2 and a side wall which is coupled to the peripheral portion of the upper wall and joined to the peripheral portion of the metal substrate 2. In addition, the thermoelectric device 51 further includes the spray deposit 35 contacting the inner surface of the lid 24, and the metal thin wire nets 9 contacting the electrodes of the thermoelectric elements 3 and contacting the spray deposit 35. The insulating layer 6 is provided in the center portion of the surface of the metal substrate 2, and the conductive wiring layers 37 are put on the insulating layer 6.

The lid 24 in the first variation is identical in configuration to the lid 4 in the first embodiment. Therefore, there is no necessity to provide the frame body 39 in the second embodiment to the peripheral portion of the surface of the metal substrate 2, and thus the number of articles can be reduced. For example, the lid 24 in the first variation is formed of Kovar or stainless, and a thickness of the member is set to 0.2 mm or less.

Also, the lid 24 is constructed by forming integrally the lid 34 and the frame body 39 in the second embodiment, and metallic joined to the metal substrate 2 by the laser welding. Here, the joinability between the lid 24 and the metal substrate 2 can be improved by interposing the joining metal member 5 such as a nickel (Ni) foil, or the like, for example.

The through hole wiring 13 provided to pass through the metal substrate 2 and the insulating layer 6 is connected to the metal layer 14 at the portion that is exposed to the outside of the metal substrate 2, and then the metal layer 14 is connected to the external electrode 16 via the solder 15. Thus, an electromotive force generated in the thermoelectric elements 3 can be picked up to the outside.

The metal substrate 2 and the lid 24 formed in this manner are metallic joined mutually by the laser, for example, and thus the internal space C2 in which the thermoelectric elements are aligned between them is produced. An inside of the internal space C2 is set to the low pressure atmosphere by utilizing a sealing hole 4b that is provided previously in the lid 24, or the atmosphere is also set to the nonoxidizing atmosphere by filling nitrogen, argon, or the like, and then the internal space C2 is hermetically sealed by fusing the sealing hole 4b by virtue of the laser. Accordingly, the thermoelectric device 51 having a hermetically sealed structure can be obtained.

According to the thermoelectric device 51 manufactured in this manner, since the lid 24 is shaped into the structure having the upper wall whose inner surface opposes to the surface of the metal substrate 2 and the side wall which is coupled to the peripheral portion of the upper wall and joined to the peripheral portion of the metal substrate 2, the number of articles can be reduced. At the same time, there is no need to provide the cap-type electrode and the insulating plate, and merely the spray deposit 35 and the metal thin wire nets 9 are provided between the inner surface of the lid 24 and the thermoelectric elements 3. Therefore, since a larger number of thermoelectric elements 3 can be provided on the surface of the metal substrate 2, the output density can be increased and also mechanical contacts between the heat source and the thermoelectric elements are reduced by reducing the number of articles to lower the heat resistance. As a result, the power generation performance provided to the internal space C2 in the thermoelectric device 51 can be improved while reducing the number of articles, and the thermoelectric device 51 that is excellent in reliability can be realized, and also the thermoelectric device 51 can be manufactured at a low cost and with good productivity.

(Second Variation)

Next, a second variation of the second embodiment of the present invention will be explained hereunder.

In the first variation, the lid 24 is joined to the peripheral portion on the surface of the metal substrate 2 via the metal joining member 5. This second variation is different in that the lid is joined to the peripheral portion on the back surface of the metal substrate 2. That is, the spray deposit 35 in the second embodiment is provided to the thermoelectric device 1 shown in the first variation of the first embodiment.

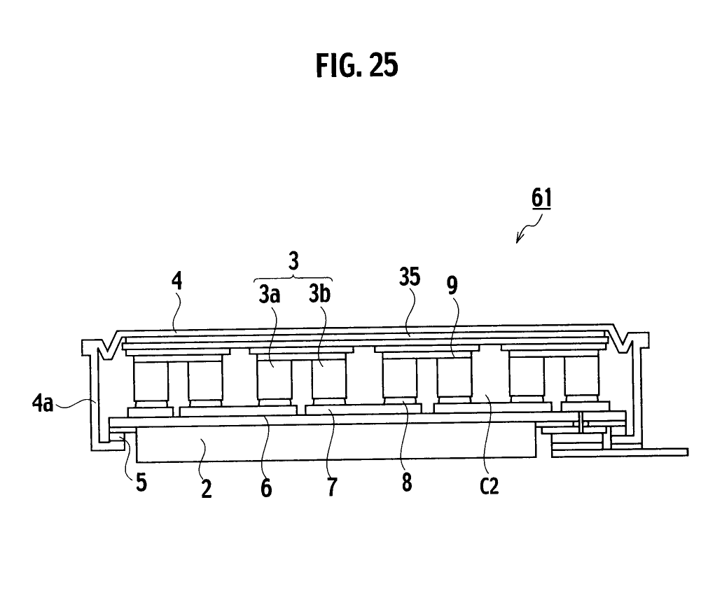

As shown in FIG. 25, the frame body 4a of the portion for covering the side surfaces of the thermoelectric elements 3 is constructed to go around to the back surface of the metal substrate 2, and the frame body 4a and the peripheral portion of the back surface of the metal substrate 2 are joined together via the joining metal member 5. Therefore, the joining area to the frame body 4a can be secured sufficiently on the back surface of the metal substrate 2 in comparison with the surface of the metal substrate 2. A thickness of the metal substrate 2 in this joining area (the peripheral portion of the back surface of the metal substrate 2) is set thinner than that of the center portion of the back surface of the metal substrate 2. Thus, an alignment of the joining metal member 5 can be made easily, and also the frame body 4a (the joining area) is not protruded from the center portion of the back surface of the metal substrate 2. In addition, the spray deposit 35 contacting the inner surface of the lid 4, and the metal thin wire nets 9 contacting the electrodes of the thermoelectric elements 3 and the spray deposit 35 are provided.

In this fashion, the frame body 4a is joined to the back surface of the metal substrate 2 not to provide the joining area on the surface of the metal substrate 2. Therefore, the surface of the metal substrate 2 can be utilized effectively as the mounting area of the thermoelectric elements 3, and thus a larger number of thermoelectric elements 3 can be arranged. At the same time, there is no need to provide the cap-type electrode and the insulating plate, and merely the spray deposit 35 and the metal thin wire nets 9 are provided between the inner surface of the lid 4 and the thermoelectric elements 3. Therefore, the output density can be increased and also mechanical contacts between the heat source and the thermoelectric elements are reduced by reducing the number of articles to lower the heat resistance. As a result, the power generation performance provided to the internal space C2 in a thermoelectric device 61 can be improved while reducing the number of articles, and the thermoelectric device 61 that is excellent in reliability can be realized, and also the thermoelectric device 61 can be manufactured at a low cost and with good productivity.

### Third Embodiment

Next, a third embodiment will be explained hereunder. In the third embodiment, the same reference symbols are affixed to the same constituent elements as those explained in the first embodiment, and thus their redundant explanations of the same constituent elements will be omitted herein.

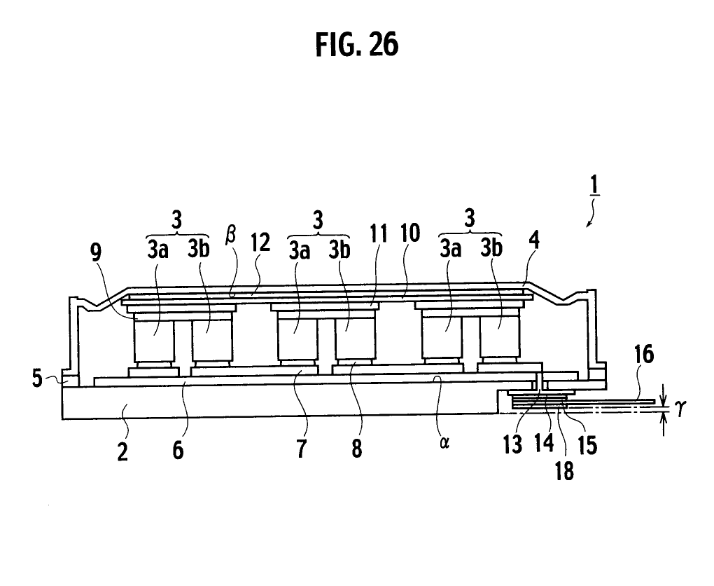

FIG. 26 is a sectional view of the thermoelectric device 1 according to the third embodiment. The electromotive force generated from the thermoelectric elements 3 is taken out to the outside of the thermoelectric device 1 to pass through the through hole wiring 13, the metal layer 14, the solder 15, and the external electrode 16 respectively. In the third embodiment, an insulating material 18 to insulate from the cooling medium is provided on the surface opposing to the surface that is connected to the solder 15 of the external electrode 16.

In the thermoelectric device 1, etc, in above respective embodiments, thicknesses of the metal substrate 2, and the like are reduced in the area of the through hole wiring 13, which is used to output the electromotive force, to include the external electrode 16, etc. therein. A resultant thickness obtained after the through hole wiring 13, the metal layer 14, the solder 15, and the external electrode 16 are stacked is identical to the back surface of the metal substrate 2.

In the third embodiment, a stacked thickness of the through hole wiring 13, the metal layer 14, the solder 15, the external electrode 16, and the insulating material 18 provided in the area of the through hole wiring 13 to output the electromotive force becomes thinner than the back surface of the metal substrate 2 by a length γ (becomes depressed when viewed from the surface of the metal substrate 2). That is, a distance from the back surface of the metal substrate 2 to a joined surface between the through hole wiring 13 and the metal layer 14 is longer than a distance from the insulating material 18 to a joined surface between the through hole wiring 13 and the metal layer 14 by a length γ.

In other words, since a stacked thickness of the through hole wiring 13 to the insulating material 18 becomes thick by providing the insulating material 18, for example, such a situation may be considered that, when the cooling medium is brought into contact with the back surface of the metal substrate 2, a clearance is generated because of a total thickness from the through hole wiring 13 to the insulating material 18. However, with such arrangement, it is possible to avoid an increase of the heat resistance due to the clearance generated between the cooling medium and the back surface of the metal substrate 2. Therefore, the heat radiation from the thermoelectric device 1 can be executed effectively and thus the power generation efficiency of the thermoelectric elements 3 can be improved. As a result, the power generation performance of the thermoelectric device 1 can be improved further more.

### Fourth Embodiment

Next, a fourth embodiment will be explained hereunder. In the fourth embodiment, the same reference symbols are affixed to the same constituent elements as those explained in the first embodiment, and thus their redundant explanations of the same constituent elements will be omitted herein.

In the fourth embodiment, there is such a feature that the metal thin wire nets 9 used in above embodiments are wrapped up with a metal foil. A metal thin wire net 9a wrapped up with this metal foil (referred to as a “metal thin wire net with foil 9a” hereinafter) can be manufactured by the following method, for example.

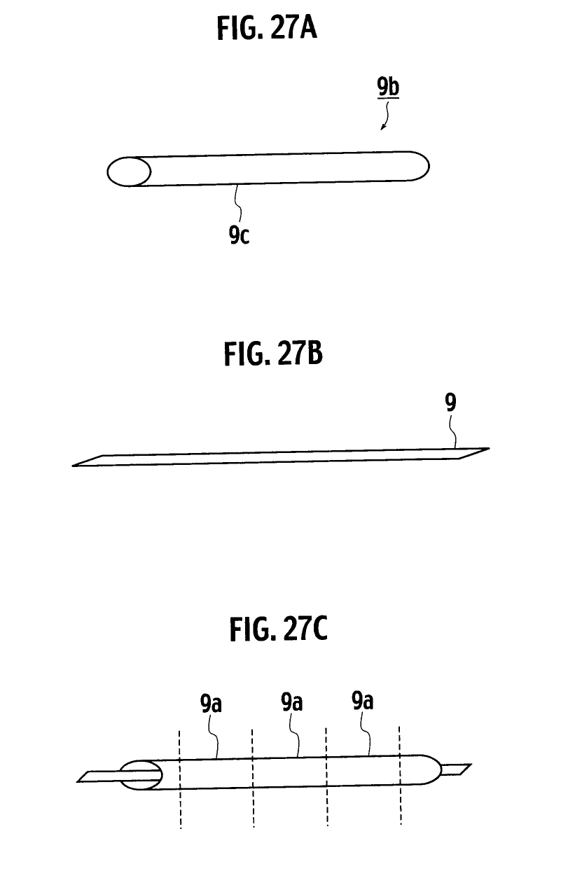

First, as shown in FIG. 27A, a cylindrical metal foil 9c formed by welding a metal foil 9b like a circular cylinder and the metal thin wire nets 9 shown in FIG. 27B are prepared. Then, the metal thin wire net with foil 9a is manufactured by passing the metal thin wire net 9 through the cylindrical metal foil 9c (see FIG. 27C) and then cutting this cylindrical metal foil 9c into an appropriate size, as indicated by a dotted line.

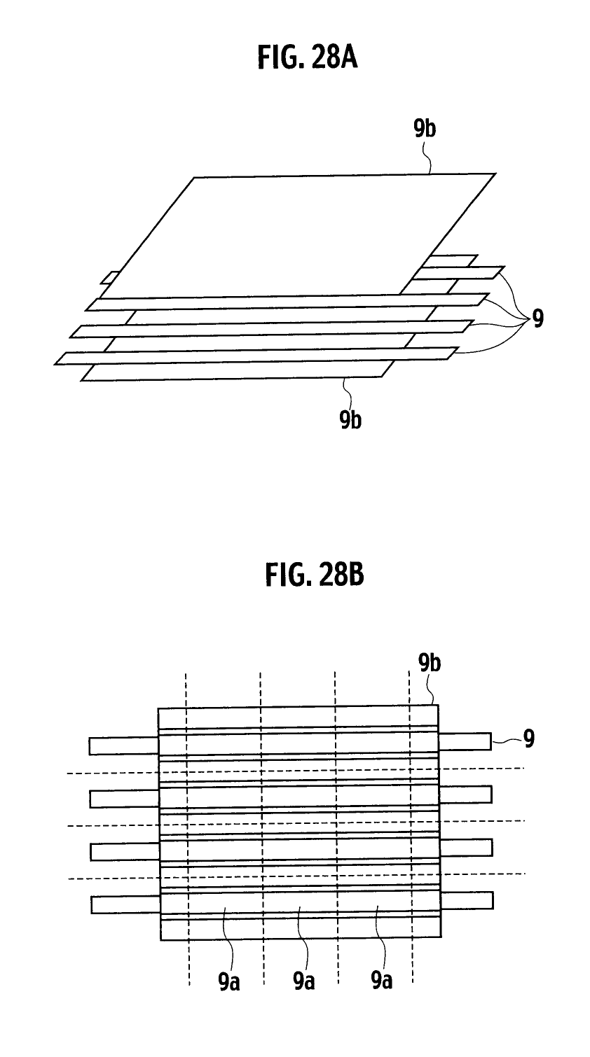

Also, the metal thin wire net with foil 9a may be manufactured by the method shown in FIG. 28, for example. That is, as shown in FIG. 28A, the metal thin wire nets 9 are put between two sheets of metal foils 9b and then the metal foils 9b are welded on both sides of the metal thin wire nets 9 (see FIG. 28B). Then, desired metal thin wire nets with foil 9a are obtained by cutting a plurality of welded metal thin wire nets with foil 9a into a desired size indicated by a dotted line.

Because such metal thin wire nets with foil 9a are employed, an adhesiveness between the metal thin wire nets 9 and the thermoelectric elements 3 can be increased and also a reduction of the heat resistance can be achieved. Also, because the metal thin wire nets 9 are wrapped up with the metal foil 9b, such a situation can be prevented that the Cu thin wire of the metal thin wire nets 9 is broken and dropped to come into contact with the first wiring layers 7, etc. and cause a short circuit, and thus the improvement in the power generation performance can be attained much more. In addition, because metal thin wire nets with foil 9a can be absorbed and handled in manufacturing the thermoelectric device 1, and the like, the step of putting the metal thin wire nets 9 on the thermoelectric elements 3 can be automated and also a productivity of the thermoelectric device 1, and the like can be improved.

### Fifth Embodiment

Next, a fifth embodiment will be explained hereunder. In the fifth embodiment and a variation of the fifth embodiment, the same reference symbols are affixed to the same constituent elements as those explained in the first embodiment, and thus their redundant explanations of the same constituent elements will be omitted herein.

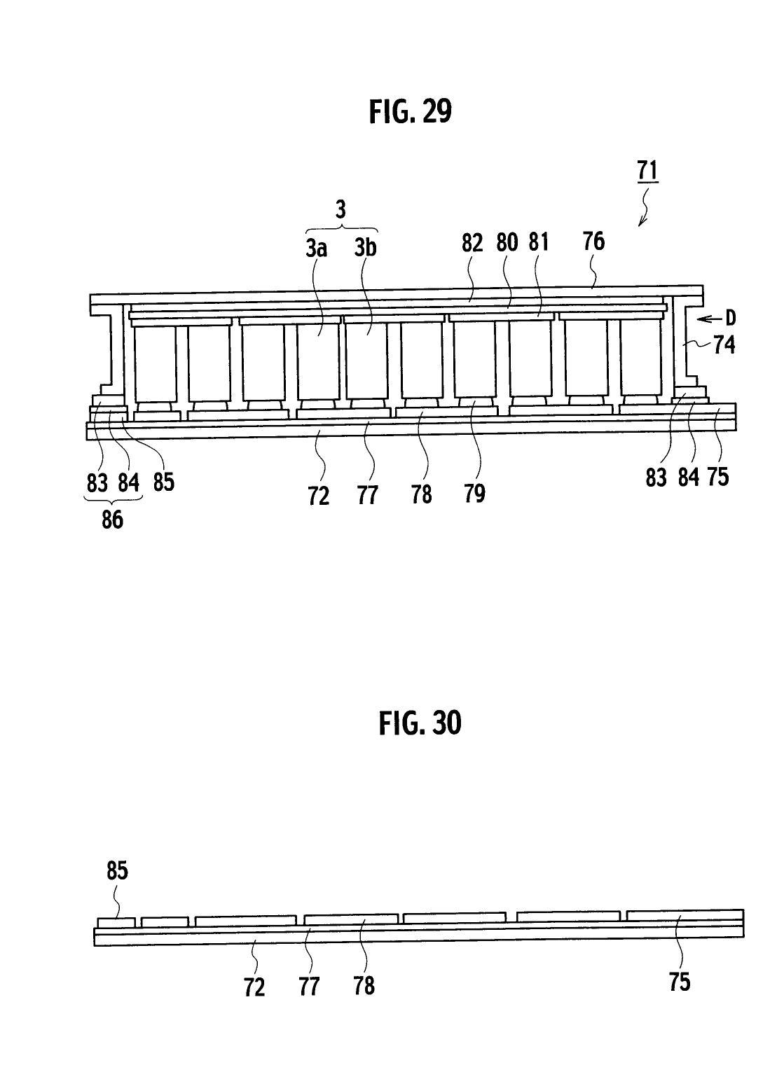

As shown in FIG. 29, a thermoelectric device 71 according to the fifth embodiment of the present invention includes a metal substrate 72, the thermoelectric elements 3 put on a center portion of the surface of the substrate 72, a frame body 74 joined to the peripheral portion of the surface of the substrate 72 to surround the thermoelectric elements 3 on its inside, leading wirings 75 whose one ends are connected electrically to the thermoelectric elements 3 on the surface of the substrate 72 and whose other ends are connected to the external electrode extended to the outside from the frame body 74, and a lid 76 arranged to oppose to the surface of the substrate 72 and seal the thermoelectric elements 3 in the space that is formed by this lid 76, the substrate 72, and the frame body 74.

A first insulating film 77 is provided on the surface of the metal substrate 72, and first conductive electrodes 78 are put on the center portion of the first insulating film 77. As the first insulating film 77, preferably a resin or a resin containing ceramic powders, for example, should be employed. In the fifth embodiment, concretely copper can be employed as the substrate 72 and the first electrodes 78 and an epoxy resin containing the ceramic powders can be employed as the first insulating film 77. The thermoelectric elements 3 are joined to the first electrodes 78 via bonding material 79 such as the solder, or the like, for example.

An insulating substrate 80 is arranged on the end portions of the thermoelectric elements 3, which are not joined to the first electrodes 78. Second electrodes 81 are formed on the surface of the insulating substrate 80 (the lower surface in FIG. 29) across a pair of thermoelectric elements 3. A metal film 82 is provided on the overall area of the back surface (the upper surface in FIG. 29) of the insulating substrate 80. Because such a structure is employed that the insulating substrate 80 is put between the second electrodes 81 and the metal film 82, a mechanical strength of the insulating substrate 80 can be increased and also a contact heat resistance between the metal film 82 and the lid 76 contacting to the outside can be reduced. Thus, a temperature difference between the upper and lower ends of the thermoelectric elements 3 can be increased, and therefore the power generation capability can be improved.

The frame body 74 is joined to the substrate 72 (metal foil 83) and the lid 76 in the peripheral portion of the surface of the substrate 72 respectively to surround the thermoelectric elements 3 therein, and thus the thermoelectric device 71 is constructed as a box-shaped structure. The frame body 74 is formed of metal such as stainless (preferably SUS304), or the like, for example, and is metallic joined to the substrate 72 by putting a nickel foil between the metal foil 83 and the frame body 74 and then applying the laser welding to them.

The leading wirings 75 are provided on the surface of the substrate 72 to pass under the frame body 74. The thermoelectric elements 3 are connected electrically to the electrodes constructed in the areas of one end portions of the leading wirings 75, and the areas of the other end portions are extended to the outside of the frame body 74 to pass under the frame body 74. The areas of the other end portions act as the external electrodes, which from the electromotive force generated in the thermoelectric elements 3 is taken out to the outside of the thermoelectric device 71. In this way, because the electromotive force is output to the outside of the thermoelectric device 71 without the through hole wiring, an electric resistance generated by the through hole wiring can be eliminated and thus the power generation capability of the thermoelectric device 71 can be improved.

The lid 76 is formed of metal such as Kovar, stainless (preferably SUS304), or the like, for example. Because the same material as the frame body 74 is employed particularly, the joining between the lid 76 and the frame body 74 and the hermetic sealing can be easily attained. The lid 76 is arranged while contacting the metal film 82 to cover the upper surfaces of the thermoelectric elements 3 and oppose to the surface of the substrate 72 via the frame body 74. When the lid 76 and frame body 74 are joined together, the insulating substrate 80 (second electrode 81) put on the thermoelectric elements 3 are held and sandwiched by the lid 76 and the substrate 72 such that a pressure is applied in the longitudinal direction of the thermoelectric elements 3, i.e., the direction along which a current flows following upon the generation of the electromotive force.

In this manner, the thermoelectric device 71 has an internal space surrounded by the substrate 72, the frame body 74, the lid 76, and constitutes a box-shaped structure whose internal space is closed from the external area. The inside of the box-shaped structure is set to a low pressure atmosphere such that this box-shaped structure is hard to deform and destroy even when exposed to a high temperature, or the inside of the box-shaped structure is also hermetically sealed by setting to a nonoxidizing atmosphere.

Next, an example of a method of manufacturing (method of assembling) the thermoelectric device 71 will be explained with reference to FIG. 30 to FIG. 40 hereunder.

As shown in FIG. 30, the first insulating film 77 is provided on the surface of the metal substrate 72, and then the first electrodes 78 are joined thereto. At this time, the leading wirings 75 are joined to make the end portions of the substrate 72 and the first insulating film 77 uniform.

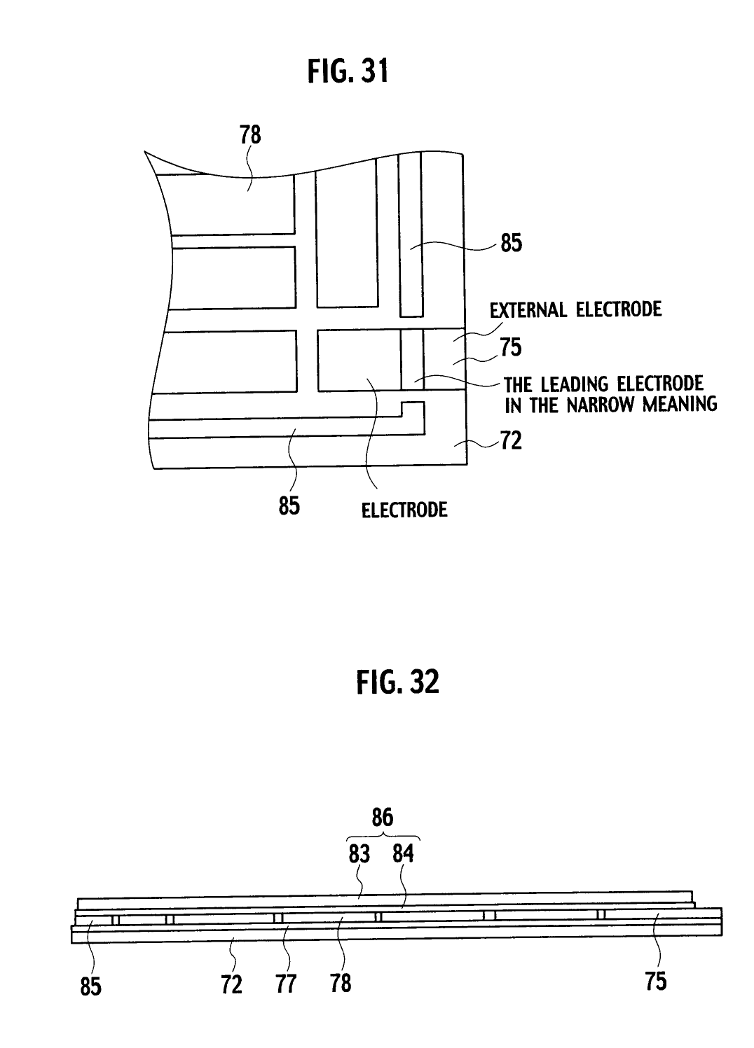

The leading wiring 75 passes under the frame body 74 in a part of area of the substrate 72 (first insulating film 77) to which the frame body 74 is connected, and then extended from the inside of the frame body 74, in which the thermoelectric elements 3 are placed, to the outside. That is, as shown in FIG. 31, the electrode area on one end, the external electrode area on the other end, and the area put between the electrode area and the external electrode area are provided to the leading wiring 75, as described above. The frame body 74 is provided onto the area put between the electrode area and the external electrode area, and is used as the leading electrode in the narrow meaning, for example. Also, in order to form the frame body 74 horizontally on the substrate 72 (first insulating film 77), the same height as the leading wiring 75 must be secured in the areas to which the frame body 74 is connected but from which the leading wiring 75 is not led. Therefore, as shown in FIG. 31 and FIG. 32, frame-body connecting metal foils 85 are formed in the areas, to which the frame body 74 is connected but from which the leading wiring 75 is not led, on the peripheral portions of the surface of the substrate 72 (first insulating film 77). Here, in FIG. 30, the surface of the substrate 72 means the upper surface to which the first insulating film 77 is joined.

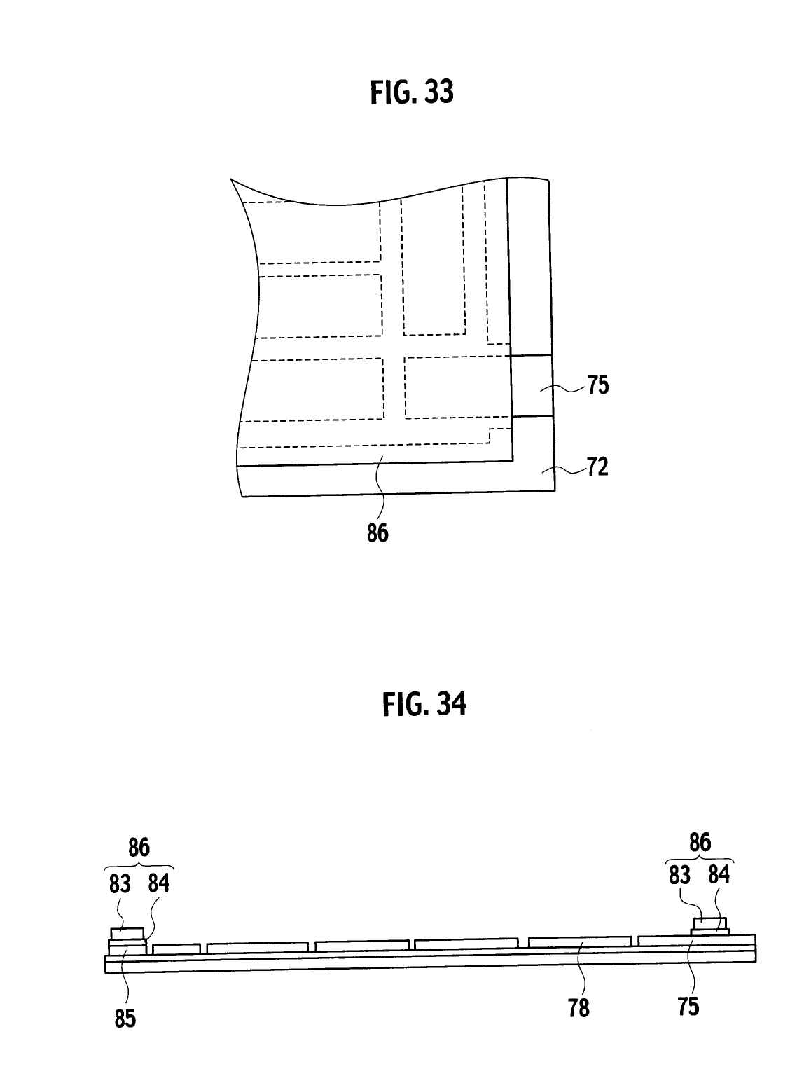

As shown in FIG. 32 and FIG. 33, a prepreg 86 in which the metal foil 83 is formed on a second insulating film 84 is pasted onto the areas of the peripheral portions of the surface of the substrate 72, to which the frame body 74 is joined, and the area of the center portion of the surface of the substrate 72, on which the thermoelectric elements 3 are mounted. That is, the outer peripheries of the frame-body connecting metal foils 85 formed on the peripheral portions of the surface of the substrate 72 and an outer periphery of the prepreg 86 coincide with each other, and also the second insulating film 84 is joined directly to the frame-body connecting metal foils 85.

When the thermoelectric device 71 is operated, the frame body 74 serves as the heat path connecting the heat absorption side and the heat radiation side but the amount of heat flowing through the inside of the frame body 74 does not contribute the power generation of the thermoelectric device 71. In the fifth embodiment, as described above, such a structure is employed that the second insulating film 84 having a low thermal conductivity is laminated between the leading wirings 75, the frame-body connecting metal foils 85 and the metal foil 83. With this arrangement, the amount of heat supplied to the thermoelectric elements 3 can be increased by reducing the amount of heat that is passed through the frame body 74 joined to the metal foil 83, and thus the power generation capability of the thermoelectric device 71 can be improved.

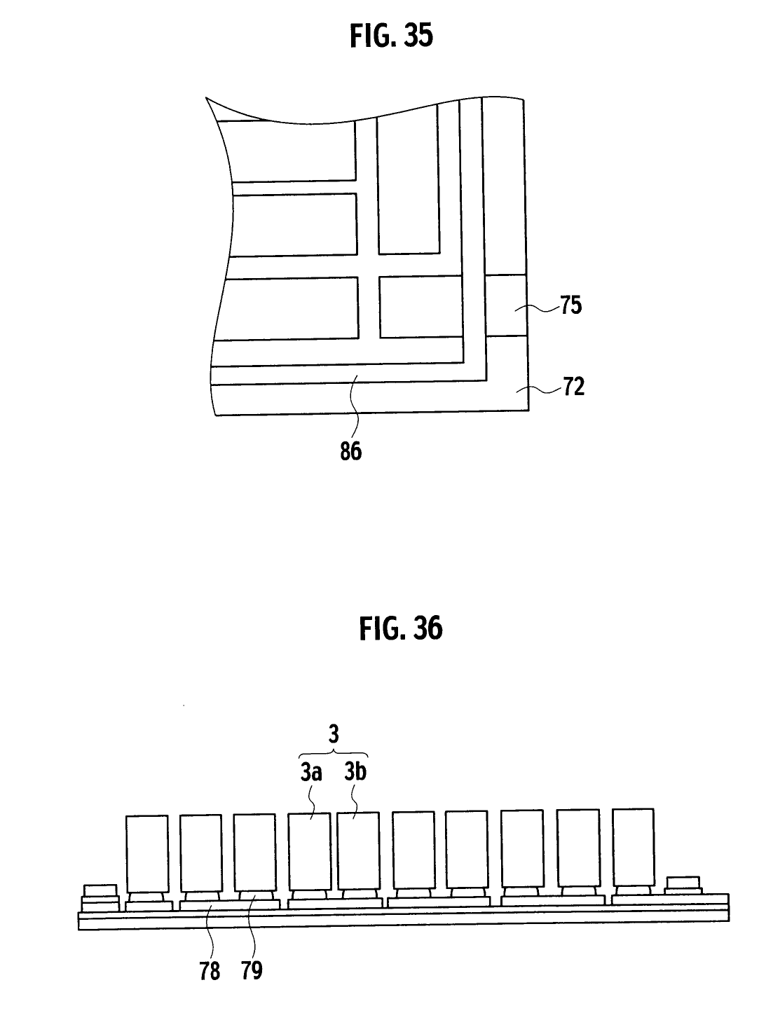

Then, as shown in FIG. 34, the prepreg 86 is removed to leave the area to which the frame body 74 is joined. As the removing method, the method of removing the metal foil by the etching and the method of removing the insulating film by the grinding may be considered. But the removing method is not limited to them. As a result, as apparent from FIG. 35, the second insulating film 84 and the metal foil 83 (prepreg 86) are formed across the leading wirings 75 to surround the thermoelectric elements 3 therein. In this case, because the second insulating film 84 is formed between the leading wirings 75 and the metal foil 83, disadvantages such as a short circuit between the leading wirings 75 and the metal foil 83, and the like can be prevented.

Then, as shown in FIG. 36, the joining material 79 is coated on the first electrodes 78 and then a plurality of thermoelectric elements 3a and 3b are aligned in accordance with the arrangement described in the first embodiment. Then, the first electrodes 78 and the thermoelectric elements 3a, 3b are joined mutually respectively. In this case, for example, the solder is used preferably as the joining material 79. But the material is not particularly limited if the similar effects to those in other embodiments can be achieved. Also, for example, when the solder is employed as the joining material 79, the first electrodes 78 and the thermoelectric elements 3a, 3b are collectively joined together at a temperature corresponding to the type of used solder in the reflow furnace respectively.

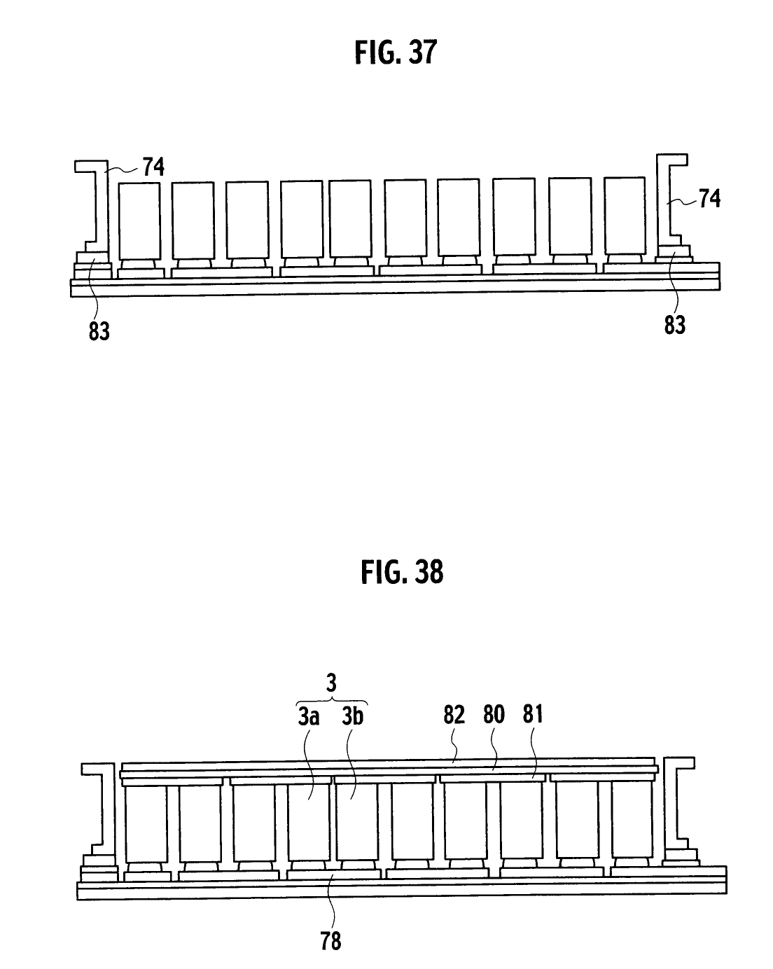

As shown in FIG. 37, the frame body 74 is joined to the metal foil 83 by the laser welding, for example. Since the portions on which the leading wirings 75 are formed and remaining portions have already been set uniform in height, there is no need to change a height of the frame body 74 depending upon the connected locations, and also the horizontality can be ensured easily over the full circumference. Also, the laser welding can heat only the joined portions locally not to heat the overall thermoelectric device 71. Therefore, the frame body 74 can be joined after the thermoelectric elements 3 and the first electrodes 78 are joined by using the joining material 79, so that the manufacture of the thermoelectric device 71 can be facilitated.

Then, as shown in FIG. 38, the insulating substrate 80 on the surface and the back surface of which the second electrodes 81 and the metal film 82 have already been provided respectively is put thereon. In particular, the second electrode 81 is put to cross the thermoelectric elements 3a and 3b (connect electrically them). Thus, a plurality of p-type thermoelectric elements 3a and a plurality of n-type thermoelectric elements 3b are alternately connected electrically in series between the first electrodes 78 and the second electrodes 81. In this step, the insulating substrate 80 is not connected to the thermoelectric elements 3 but simply put thereon.

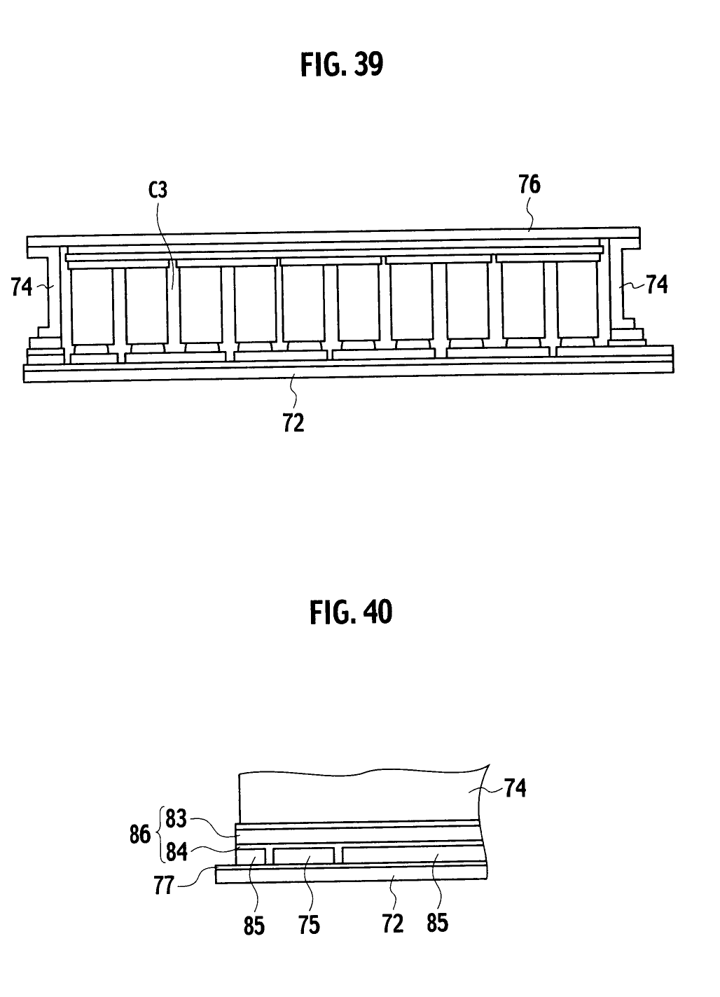

Then, as shown in FIG. 39, the lid 76 and the frame body 74 are joined together by the laser welding. Since the frame body 74 is joined to the metal foil 83 while keeping its horizontal posture on the surface of the substrate 72, as described above, the lid 76 can be joined to the frame body 74 to maintain the hermetic sealing. In the fifth embodiment, SUS304 is used as the materials of the lid 76 and the frame body 74. But the materials of the lid 76 and the frame body 74 are not limited to this material if the hermetic sealing can be maintained.

In this manner, because the lid 76 and the substrate 72 are joined via the frame body 74, an internal space C3 in which the thermoelectric elements are aligned between them is produced. This internal space C3 is set to a low pressure atmosphere by utilizing a sealing hole (not shown) that is provided previously in the lid 76. Also, the internal space C3 is brought into a nonoxidizing atmosphere by filling nitrogen, argon, or the like, and then the sealing hole is melt by the laser to hermetically seal the internal space. Accordingly, the thermoelectric device 71 having the hermetic sealing structure can be obtained.

In this manner, the electromotive force generated by the thermoelectric elements 3 is taken out to the outside not via the through hole wiring but via the leading wirings 75 formed on the metal substrate 72. Therefore, an increase of electric resistance caused by providing the through hole wiring can be prevented.

As shown in FIG. 40 depicted when the thermoelectric device 71 is viewed from the direction D indicated by an arrow in FIG. 29, the frame-body connecting metal foils 85 having the same height as the leading wirings 75 are formed in the areas, where the frame body 74 is connected to the substrate 72 but the leading wirings 75 are not formed, of the substrate 72. As a result, the frame body 74 and the lid 76 are joined to the substrate 72 horizontally respectively, and thus the hermetic sealing in the internal space C3 can be maintained.

Accordingly, the electric resistance of the thermoelectric device can be reduced with a simple configuration, and also the generated electricity can be taken out effectively to the outside. Also, the thermoelectric device 71 that can improve the power generation performance of the thermoelectric elements 3, which are provided in the internal space C3 in the thermoelectric device 71, while maintaining the hermetic sealing and that has the excellent reliability can be realized, and also the thermoelectric device 71 can be manufactured simply.

(First Variation)

Next, a first variation of the fifth embodiment will be explained hereunder.

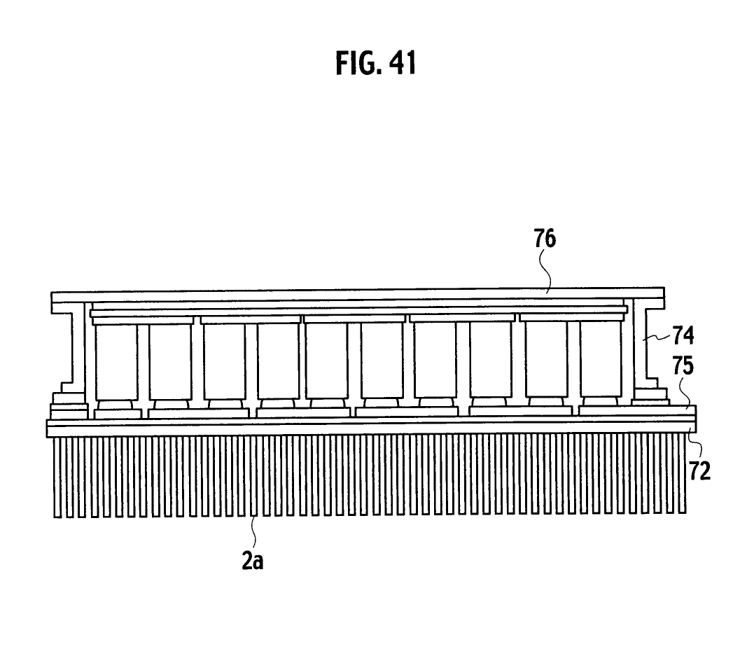

As shown in FIG. 41, the thermoelectric device 71 according to the first variation is characterized in that the fins 2a are provided on the back surface of the substrate 72. As explained in the fifth embodiment, the electromotive force generated in the thermoelectric device 71 is output to the outside by utilizing the leading wirings 75 formed on the surface of the metal substrate 72. In other words, there is no need to connect the external electrode to the back surface of the substrate 72 unlike the case where the through hole wiring is utilized, and the back surface of the substrate 72 can be kept in a flat surface condition without the unevenness.

Accordingly, since the fins 2a having a high heat exchange effect are provided on the flat back surface of the substrate 72, the heat exchange efficiency of the thermoelectric device 71 can be improved and also the power generation efficiency of the thermoelectric elements 3 can be improved. Therefore, the power generation performance of the thermoelectric device 71 can be improved further more.

In the first variation, since the metal that can be processed easily by the machining is employed as the substrate 72, the fins 2a can be manufactured by processing the back surface of the substrate 72 by virtue of the cutting, the etching, or the like. Also, the fins 2a are not manufactured by processing the back surface of the substrate 72 but fitted to the back surface of the substrate 72 as the separate body from the substrate 72. In addition, as explained in the fifth variation of the first embodiment (see FIG. 13), the heat exchange jacket 2b may be fitted or the fins 2a and the heat exchange jacket 2b may be used together in combination.

### Sixth Embodiment

Next, a sixth embodiment will be explained hereunder. In the sixth embodiment and respective variations of the sixth embodiment, the same reference symbols are affixed to the same constituent elements as those explained in the first embodiment, and thus their redundant explanations of the same constituent elements will be omitted herein.

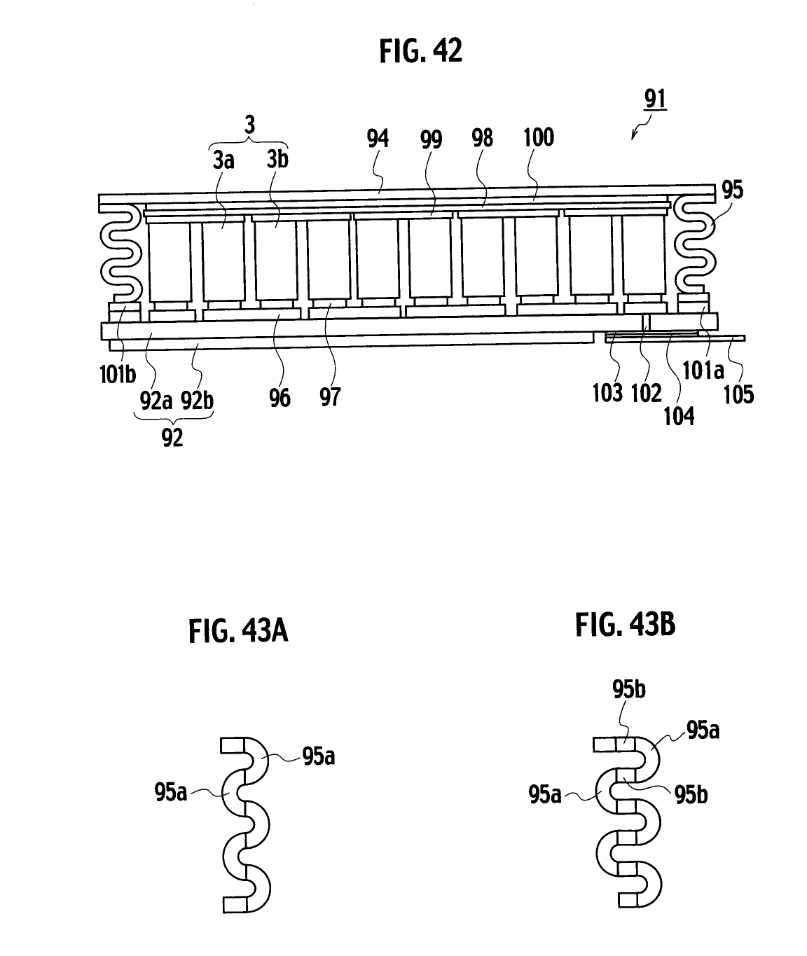

As shown in FIG. 42, a thermoelectric device 91 according to the sixth embodiment of the present invention includes a substrate 92, the thermoelectric elements 3 mounted on a surface of the substrate 92, a lid 94 arranged to oppose to the substrate 92 and interpose the thermoelectric elements 3 between them, and a frame body 95 having a high heat resistance shaped portion one end of which is joined to the peripheral portion of the substrate 92 to surround the thermoelectric elements 3 therein and the other end of which is joined to the peripheral portion of the lid 94.

The substrate 92 is constructed by a first insulating substrate 92a, and a metal foil 92b provided to the back surface of the first insulating substrate 92a. First conductive electrodes 96 are put on a center portion of the surface of the first insulating substrate 92a. As the first insulating substrate 92a, a resin or a resin containing ceramic powders is preferably used, in addition to the ceramic plate the sixth embodiment, as shown in FIG. 42, for example. The metal foil 92b may be formed on the back surface of the first insulating substrate 92a by the joining, the deposition, or the like, for example. As the metal foil 92b, for example, copper can be used preferably. The thermoelectric elements 3 are joined to the first electrodes 96 via a first bonding material 97 such as the solder, or the like, for example.

A second insulating substrate 98 is arranged on the end portions of the thermoelectric elements 3, which are not joined to the first electrodes 96. Second electrodes 99 are formed on the surface (the lower surface in FIG. 42) of the second insulating substrate 98 to cross a pair of thermoelectric elements 3, and a metal film 100 is provided on a whole area of the back surface (the upper surface in FIG. 4) of the second insulating substrate 98. The metal film 100 can enhance the mechanical strength of the second insulating substrate 98. In addition, the metal film 100 can improve a substantive contact of the second insulating substrate 98 with respect to a lid 94 and thus reduce a heat resistance, thereby enhancing a heat exchange efficiency with the exterior.

The lid 94 is formed of a metal such as Kovar, stainless (preferably SUS304), or the like, for example, and is placed in a position that covers the upper surfaces of a plurality of thermoelectric elements 3 while contacting the metal film 100 and metallic joined to the frame body 95. When the lid 94 and the frame body 95 are joined together, the second insulating substrate 98 (second electrodes 99) put on the thermoelectric elements 3 are held and sandwiched by the lid 94, the frame body 95, and the substrate 92 such that a pressure is applied in the longitudinal direction of the thermoelectric elements 3, i.e., the direction along which a current flows in answer to the generation of the electromotive force. Also, if the same metal as the frame body 95 is employed as the lid 94, for example, a stress generated at the joined portion between the lid 94 and the frame body 95 can be reduced, and also the airtightness can be easily secured.

The frame body 95 joins the substrate 92 and the lid 94 arranged in a position opposing to the substrate 92 in the peripheral portion of the surface of the substrate 92 to surround the thermoelectric elements 3 in its inside, and connects them. The thermoelectric device 91 is shaped into a box-shaped structure via the frame body 95. The frame body 95 is formed of a metal such as stainless (preferably SUS304), or the like, for example, and is metallic joined to the lid 94 and the substrate 92 via a frame body bonding metal foil 101a and a nickel foil 101b respectively. As a frame body bonding metal foil 101, a metal foil such as a copper foil can be used.

Also, the thermoelectric device 91 has a space in the inside surrounded by the substrate 92 and the lid 94, and this internal space can be hermetically sealed from the outside. The inside of the box-shaped structure is set to a low pressure atmosphere such that this box-shaped structure is hard to deform and destroy even when exposed to a high temperature. Respective thermoelectric elements 3 are hermetically sealed in the box-shaped structure in which the low pressure atmosphere is maintained.

Meanwhile, the “heat resistance” indicates a temperature rise when an electric power of 1 W is applied, and the heat resistance is increased in proportion to a length (distance). Therefore, in the embodiments of the present invention, since a length of the frame body 95 is set longer than a clearance between the substrate 92 and the lid 94, the heat resistance of the frame body 95 is increased and also the amount of heat flown to the frame body 95, so that the larger amount of heat is supplied to the thermoelectric elements 3. As a consequence, an improvement of the power generation performance of the thermoelectric device 91 can be attained.

The frame body 95 according to the sixth embodiment is not shaped to have a linear sectional shape. In order to increase the heat resistance, as shown in FIG. 42, the frame body 95 is formed by shaping the member such that a portion constituting a ridge and a portion constituting a root appears laterally alternately in a sectional shape from the peripheral portion of the substrate 92 to the peripheral portion of the lid 94.

In more detail, in order to lengthen the frame body 95 between the substrate 92 and the lid 94, as shown in FIG. 42, the members are joined such that a portion constituting a ridge and a portion constituting a root appears alternately from the substrate 92 to the lid 94, and also the number of circular arcs (folds) is increased by reducing a radius of the bent portion as small as possible. For example, in case a length from the surface of the frame body bonding metal foil 101 contacting the frame body 95 to the back surface of the lid 94 is set to 20 mm and a thickness of the frame body 95 is set to 0.25 mm, a radius of the bent portion can be reduced to about 0.5 mm by the plastic working. In this case, as shown in FIG. 43A, the number of folds of the frame body 95, which extend toward the outside of the thermoelectric device 91, is nine and a total length of the frame body 95 becomes about 31 mm.

Also, in the case as shown in FIG. 43B, a total length of the frame body 95 becomes about 40 mm and is twice longer than the normal length from the surface of the frame body bonding metal foil 101 to the back surface of the lid 94.

Since the heat resistance is increased in proportion to a length (distance), such heat resistance also becomes twice when the total length is increased almost twice. When a capacity of the heat source to which the thermoelectric device 91 is fitted is limited small in this condition, a ratio of the amount of heat supplied to the thermoelectric elements 3 to the amount of heat flowing through the frame body 95 ranges 6:4 to 7.5:2.5. Therefore, since the amount of heat supplied to the thermoelectric elements 3 is increased 1.25 times, the power generation performance of the thermoelectric device 91 can be improved.

In addition, for example, the molding bellows can be utilized as the frame body 95. The molding bellows is produced by shaping a pipe in line with the folds provided on the die under the condition that, while the pipe made of the material constituting the frame body 95 is passed through and held in the die on the inside of which the folds are formed previously, a large quantity of fluid such as water, oil, or the like is passed through the pipe to expand the pipe outward by a pressure of the fluid. Also, the manufacturing method of forming the folds by applying the drawing working to push the pipe made of the material constituting the frame body 95 from the inside to the outside, or the like may be employed. For example, the molding bellows shaped as above can be utilized as the frame body 95 when the thermoelectric device 91 is a cylindrical structural body, while the molding bellows that is further processed by shaping the bellows into a rectangular shape in terms of the plastic working can be utilized as the frame body 95 when the box-shaped structure is employed. Also, the frame body 95 can be formed by shaping the flat plate to the corrugated plate, then bending the plate, and then welding both ends like a ring.

The frame body 95 is joined to the substrate 92 and the lid 94 in such a way that one end and the other end of the frame body 95, which are joined to the substrate 92 or the lid 94, are directed to the outside of the thermoelectric device 91. In this case, sometimes the explanation is given as if the substrate 92 and the frame body 95 are directly joined to each other, but actually both members are joined via the frame body bonding metal foil 101a and the nickel foil 101b, as described above.

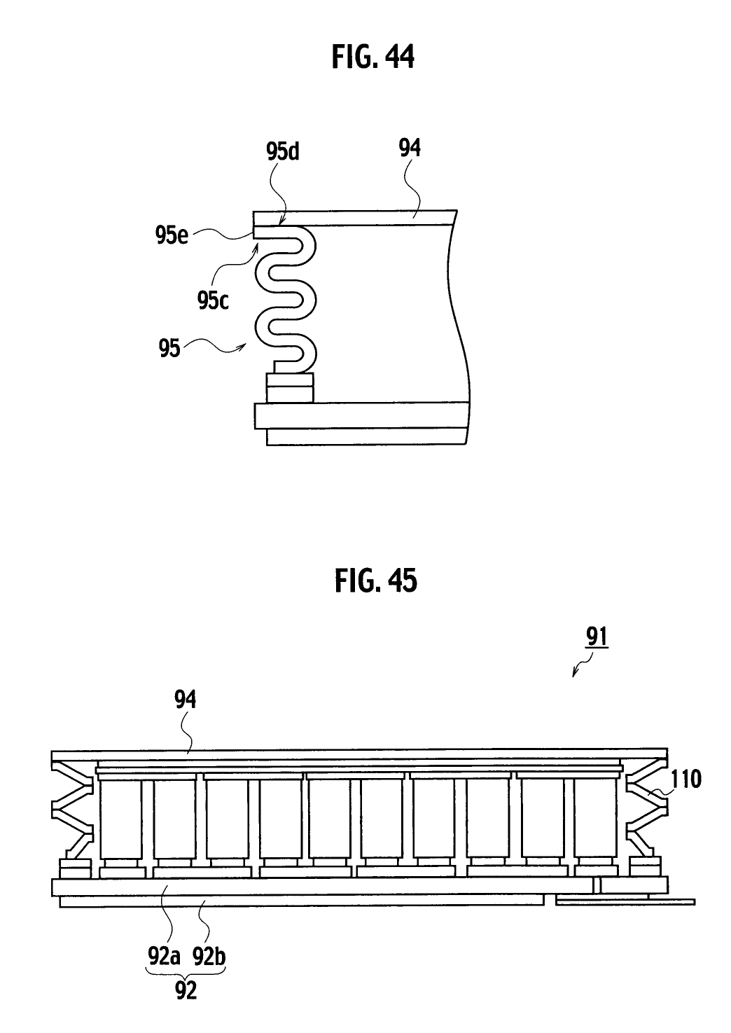

Then, explanation will be made hereunder by taking the joined portion between the lid 94 and the frame body 95 as an example. As shown in FIG. 44, the frame body 95 has a second joining area 95d joined to the lid 94 at the other end 95c. An other end surface 95e of the other end 95c is arranged on the peripheral side of the lid 94, and the lid 94 and the frame body 95 are joined together via the second joining area 95d. One end of the frame body 95 joined to the substrate 92 is arranged similarly, and is joined to the substrate 92.

Because the frame body 95 is arranged in such direction to the substrate 92 and the lid 94, their mutual joining can be executed more easily.

A through hole wiring 102 provided to pass through the substrate 92 and the first insulating substrate 92a is connected to an external electrode 103 in the portion that is exposed further to the outside of the substrate 92. Then, the external electrode 103 is connected to an external electrode 105 via a second bonding material 104. Thus, the electromotive force generated in the thermoelectric elements 3 is output to the outside.

In this manner, the members are joined such that the portion constituting the ridge and the portion constituting the root appears alternately from the substrate 92 to the lid 94 in a sectional shape of the frame body 95. Therefore, since the total length of the frame body 95 can be lengthened, the heat resistance of the frame body 95 can be increased and also a larger amount of heat can be transmitted to the thermoelectric elements 3 from the outside. As a result, the power generation performance can be improved while keeping the hermetically sealed condition, and the thermoelectric device 91 whose reliability is excellent can be realized.

(First Variation)

Next, a first variation of the sixth embodiment will be explained hereunder.

As shown in FIG. 45, a configuration of the first variation is different in a shape of a frame body 110 from the configuration shown in the sixth embodiment. In the sixth embodiment, the frame body 95 is formed by shaping the member such that a portion constituting a ridge and a portion constituting a root appears laterally alternately in a sectional shape from the peripheral portion of the substrate 92 to the peripheral portion of the lid 94. In the first variation, the frame body 110 is constructed by joining a ridge portion whose internal angle between two sides is an acute angle and a root portion whose external angle between two sides is an acute angle alternately in a sectional shape from the substrate 92 to the lid 94.

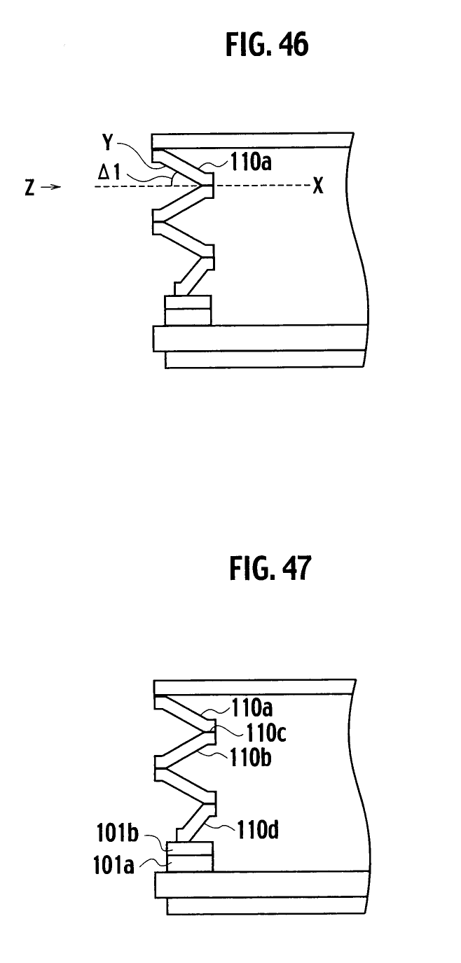

In other words, as shown in FIG. 45 and FIG. 46, assume that a line drawn in parallel with a joined surface between a constituent member 110a and another constituent member 110a as the constituent members of the frame body 110 is X (see FIG. 46), and angle between two sides consisting of this line X and a line Y appeared on a surface of the constituent member 110a is Δ1. Here an angle Δ1 is 90 degree or less. In this case, the case where the ridge is formed toward the inside of the thermoelectric device 91 when the frame body 110 is viewed from the outside (from a position Z) of the thermoelectric device 91 is defined as the ridge portion, and conversely the case where the ridge is formed toward the outside of the same when the frame body 110 is viewed from the outside is defined as the root portion. The frame body 110 is constructed by joining alternately the ridge and the root from the substrate 92 to the lid 94. Concretely, the frame body 110 is manufactured by stacking ring-like flat plates in a center portion of which a hole is formed, and then joining alternately peripheral portions of the holes provided in the center portion of the flat plates and peripheral portions of the flat plates.

In more detail, for example, a length from the surface of the frame body bonding metal foil 101 to the back surface of the lid 94 is assumed as 10 mm, and a thickness of the frame body 110 is assumed as 0.25 mm in the position where the frame body 110 is provided. Also, when the frame body 110 is manufactured by stacking eight sheets of flat plates (described later), a total length of the frame body 110 is 24 mm and the length becomes 2.4 times. As described above, because the heat resistance is in proportion to a length (distance), the heat resistance becomes 2.4 times. Therefore, because the heat resistance of the frame body 110 is increased, the amount of heat supplied to the thermoelectric elements 3 is increased rather than that attained up to now, and thus the power generation performance of the thermoelectric device 91 can be improved.

Here, the frame body 110 is joined to the substrate 92 and the lid 94 in such a way that one end and the other end of the frame body 110, which are joined to the substrate 92 or the lid 94, are directed to the outside of the thermoelectric device 91.

In this manner, the total length of the frame body 110 is prolonged by joining the ridge portion whose internal angle between two sides is an acute angle and the root portion whose external angle between two sides is an acute angle alternately in a sectional shape from the substrate 92 to the lid 94. Therefore, the heat resistance can be increased and also a larger amount of heat can be transmitted to the thermoelectric elements 3 from the outside. As a result, the power generation performance can be improved while keeping the hermetically sealed condition, and the thermoelectric device 91 whose reliability is excellent can be realized. Also, when the frame body 110 is manufactured by the above manufacturing method, the frame body 110 can be manufactured easily.

(Second Variation)

Next, a second variation of the sixth embodiment will be explained hereunder.

In the second variation, the frame body 110 is constituted of an increased number of constituting members, which are for example the constituent members 110a, 110b as shown in FIG. 47, when explained with reference to the frame body 110 shown in the first variation. When the constituent members 110a,110b are joined together by laser-welding for example, at a jointed surface 110c, the heat resistance in the frame body 110 is increased, thereby improving the power generation performance of the thermoelectric device 91. By the way, these constituent members constituting the frame body 110 is formed of metal such as stainless (preferably SUS304), for example.

In this manner, since the constituent members constituting the frame body 110 are welded mutually in such a fashion that the joined portions are formed in the sectional shape except the end portions of the frame body 110 in any sectional shape containing the lid 94 and the substrate 92, the heat resistance the frame body 110 is increased. Also, the heat resistance is increased even when the frame body 110 and the substrate 92 are joined via the metal foil used to join the frame body 110. As a result, the amount of heat supplied to the thermoelectric elements 3 is increased much more than the ordinary one, and thus the power generation performance of the thermoelectric device 91 can be improved.

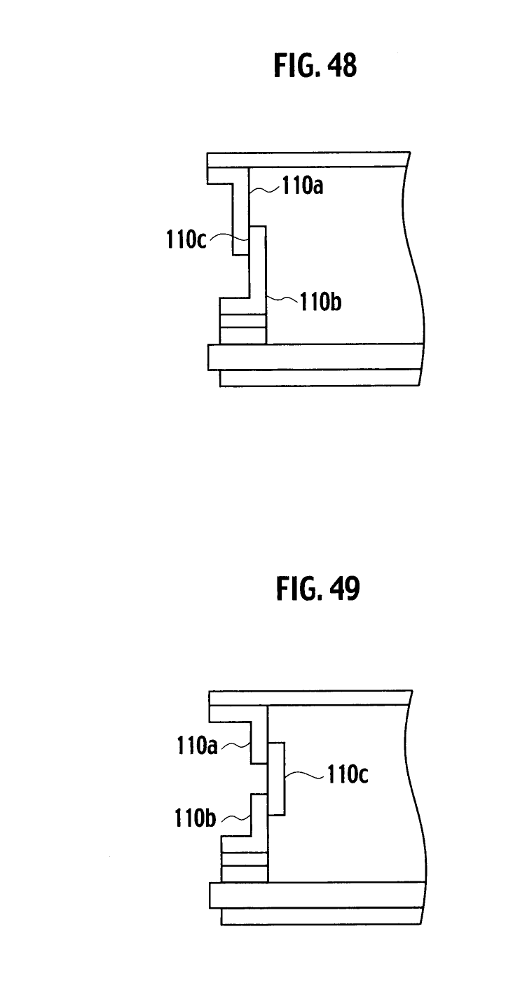

In the second variation, explanation is made by using the frame body 110 shown in the first variation. For example, as shown in FIG. 48 and FIG. 49, when a number of constituent members constituting the frame body 110 are joined, the heat resistance of the frame body 110 can be increased. Also, the case where the welding using the laser, for example, is executed is explained up to now. Further, the heat resistance can be increased by applying the brazing, for example.

Now, the present invention is not limited to the above embodiment themselves, and the present invention can be embodied by varying the constituent elements at the implementing stage within a range not departing from the scope. Also, various inventions can be produced by combining appropriately a plurality of constituent elements disclosed in the above embodiments. For example, several constituent elements may be deleted from all constituent elements disclosed in the above embodiments. In addition, the constituent elements extending over different embodiments may be combined appropriately.

What is claimed is:

1. A thermoelectric device, comprising:
a metal substrate;
a thermoelectric element mounted on a surface of the substrate;
a lid arranged to oppose to the surface of the substrate via the thermoelectric element; and
a frame body having a high heat resistance shaped portion one end of which is joined to a peripheral portion of the substrate to surround a periphery of the thermoelectric element and other end of which is joined to a peripheral portion of the lid.

2. A thermoelectric device according to claim 1, wherein the high heat resistance shaped portion is formed by shaping a member such that a plurality of bent portions appear from one end to other end.

3. A thermoelectric device according to claim 1, wherein the high heat resistance shaped portion is shaped by joining members alternately from the substrate to the lid such that a ridge portion whose internal angle between two sides is an acute angle and a root portion whose external angle between two sides is an acute angle appear alternately.

4. A thermoelectric device according to claim 1, wherein joined portions are formed in a cutting surface except end portions of the frame body in any sectional shape containing the lid and the substrate.
